(19) United States
(12) Patent Application Publication
(10) Pub. No.: US 2024/0215325 A1
(43) Pub. Date: Jun. 27, 2024

(54) DISPLAY PANEL

(71) Applicant: Samsung Display Co., Ltd., Yongin-Si (KR)

(72) Inventors: JEONGYOON LEE, Yongin-si (KR); KYUNGHO KIM, Yongin-si (KR); OK-KYUNG PARK, Yongin-si (KR)

(21) Appl. No.: 18/396,714

(22) Filed: Dec. 27, 2023

(30) Foreign Application Priority Data
Dec. 27, 2022 (KR) 10-2022-0186400

(51) Int. Cl. H10K 59/122; H10K 59/80

(52) U.S. Cl. CPC H10K 59/122; H10K 59/80521

(57) ABSTRACT

Provided is a display panel including a light-emitting device including a first electrode, a second electrode, and a light-emitting layer, a pixel defining layer having a light-emitting opening defined therein the pixel defining layer not covering at least a center portion of the first electrode, a separator disposed on the pixel defining layer and having a separating opening defined therein and overlapping the light-emitting opening, and a sensing electrode including a pattern portion overlapping the separator and a bridge portion electrically connected to the pattern portion. At least a portion of the pattern portion is disposed on the separator and electrically disconnected from the second electrode along an edge of the separator and the bridge portion is disposed on the pixel defining layer, wherein the bridge portion includes a first portion which overlaps the separator and a second portion which does not overlap the separator.

### CROSS-REFERENCE TO RELATED APPLICATIONS

This U.S. non-provisional patent application claims priority under 35 U.S.C. § 119 to Korean Patent Application No. 10-2022-0186400, filed on Dec. 27, 2022, the entire contents of which are hereby incorporated by reference.

### BACKGROUND

The present disclosure herein relates to a display panel, and more particularly, to a display panel capable of sensing and having a reduced thickness.

In general, electronic devices such as smart phones, digital cameras, notebook computers, navigation systems, and smart televisions, which provide images to a user, include a display panel for displaying images. The display panel generates images and provides the generated images to a user through a display screen.

The display panel includes pixels for generating images and sensing electrodes for sensing external inputs. When noise is generated between the sensing electrodes and electrodes in the pixels, driving signals provided to the sensing electrodes may be distorted, thus affecting sensing sensitivity. Accordingly, research is being conducted on methods for reducing noise between the sensing electrodes and the electrodes in the pixels.

### SUMMARY

The present disclosure provides sensing electrodes with improved sensing sensitivity as well as pixels with reduced afterimage defects and improved lifetime.

The present disclosure also provides a display panel with reduced thickness by providing sensing electrodes for a sensing function.

An embodiment of the inventive concept provides a display panel including: a light-emitting device including a first electrode, a second electrode, and an intermediate layer disposed between the first electrode and the second electrode and including a light-emitting layer; a pixel defining layer having a light-emitting opening defined therein, the pixel defining layer not covering at least a center portion of the first electrode; a separator disposed on the pixel defining layer and having a separating opening which is defined therein and overlaps the light-emitting opening; and a sensing electrode including a pattern portion overlapping the separator and a bridge portion electrically connected to the pattern portion, wherein at least a portion of the pattern portion is disposed on the separator and the pattern portion is electrically disconnected from the second electrode along an edge of the separator and the bridge portion is disposed on the pixel defining layer, wherein the bridge portion includes a first portion which overlaps the separator and a second portion which does not overlap the separator.

In an embodiment, the separator may include a first side surface defining the separating opening and a second side surface opposite to the first side surface, wherein an interior angle formed between the second side surface and an upper surface of the pixel defining layer may be smaller than an interior angle formed between the first side surface and the upper surface of the pixel defining layer.

In an embodiment, the separator including a connection opening, the separator not covering at least a portion of the bridge portion, a portion of an inner side surface of the separator defining the connection opening may correspond to the second side surface, and the pattern portion may be connected to the bridge portion in the connection opening.

In an embodiment, the pattern portion may include a mesh line having a mesh opening defined therein, wherein the mesh opening is disposed in a region corresponding to the separating opening to overlap the separating opening.

In an embodiment, the display panel may further include: a transistor electrically connected to the second electrode; and a connection line electrically connecting the transistor to the second electrode, wherein: the second electrode may be disposed on the first electrode in a region overlapping the light-emitting opening; and the connection line may include a first connection part connected to the second electrode and spaced apart from the light-emitting opening in a plan view and a second connection part connected to the transistor.

In an embodiment, each of the separating opening and the mesh opening may overlap both the light-emitting opening and the first connection part in a plan view.

In an embodiment, the light-emitting device may include a plurality of light-emitting devices, the light-emitting opening may include a plurality of light-emitting openings which are disposed to correspond to the plurality of light-emitting devices, respectively, the separating opening may include a plurality of separating opening which are disposed to correspond to the light-emitting openings, respectively, and the mesh opening may include a plurality of mesh openings each of which is disposed to correspond to one or more of the separating openings.

In an embodiment, the pattern portion may include: first sensing patterns arranged in a first direction; an intermediate pattern disposed between the first sensing patterns and having an integral shape with the first sensing patterns; and second sensing patterns arranged in a second direction crossing the first direction, wherein a first mesh line may include a mesh line of the first sensing patterns and the intermediate pattern, and a second mesh line may include a mesh line of the second sensing patterns.

In an embodiment, the first mesh line and the second mesh line may be disposed on the same layer and spaced apart from each other.

In an embodiment, the bridge portion may electrically connect the second sensing patterns adjacent to each other.

In an embodiment, the bridge portion may include at least one bridge line, wherein each of the at least one bridge line may include: a first connection part connected to one of the second sensing patterns; a second connection part connected to another one of the second sensing patterns disposed adjacent to the one of the second sensing patterns and spaced apart from the first connection part in the second direction; and a bent portion disposed between the first connection part and the second connection part.

In an embodiment, the bent portion may overlap the first sensing patterns and is completely overlapped with the separator.

In an embodiment, the first connection part and the second connection part may be spaced apart from each other with at least one of the light-emitting openings interposed therebetween.

In an embodiment, the separator includes a first connection opening in which the separator on a portion of the first connection part is removed, and a second connection opening in which the separator on a portion of the second connection part is removed, the one of the second sensing patterns may be connected to the first connection part though the first connection opening, and the another one of the second sensing patterns disposed adjacent to the one of the second sensing patterns may be connected to the second connection part through the second connection opening.

In an embodiment, the pattern portion may extend along an inner side surface of the separator defining the first connection opening and is connected to the bridge portion.

In an embodiment, an interior angle between an inner side surface of the separator defining the first connection opening and an upper surface of the pixel defining layer may be from about 90 degrees to about 95 degrees.

In an embodiment, the separator may include a first separator and a second separator spaced apart from each other, wherein the first mesh line may overlap the first separator and the second mesh line may overlap the second separator.

In an embodiment, a portion of the bridge portion may overlap the first separator, another portion of the bridge portion may overlap the second separator, and a remaining portion of the bridge portion may not be covered by the first separator and the second separator exposed from the first separator and the second separator, wherein the pattern portion may be connected to the remaining portion of the bridge portion.

In an embodiment, the first separator may include a first outer side surface facing the second separator and overlapping the bridge portion, and the second separator may include a second outer side surface facing the first outer side surface and overlapping the bridge portion, wherein an interior angle formed between the second outer side surface and an upper surface of the pixel defining layer may be smaller than an interior angle formed between the first outer side surface and the upper surface of the pixel defining layer.

In an embodiment, the second sensing pattern may extend along the second outer side surface and is connected to the bridge portion.

In an embodiment, the display panel may further include transistors electrically connected to second electrodes of the light-emitting devices, respectively; and connection lines electrically connecting the transistors and the second electrodes, respectively, wherein each of the connection lines may include: a first connection part connected to a corresponding second electrode among the second electrodes; and a second connection part connected to a corresponding transistor among the transistors, wherein the first connection parts of the connection lines may be disposed adjacent to each other in a predetermined arrangement to form contact groups.

In an embodiment, the bridge portion may be spaced apart from the contact groups in a plan view.

In an embodiment, the bridge portion may include a first bridge line and a second bridge line spaced apart from each other in a first direction with one of the contact groups interposed therebetween, a bent portion of the first bridge line may protrude in a direction away from the one of the contact groups from each of a first connection part and the second connection part of the first bridge line, and a bent portion of the second bridge line may protrude in a direction away from any one of the contact groups from each of the first connection part and a second connection part of the second bridge line.

In an embodiment, the display panel may further include a dummy layer disposed between the separator and the pattern portion, wherein the dummy layer may be separated from the intermediate layer along the edge of the separator.

In an embodiment, the display panel may further include an additional dummy layer disposed on a portion of the bridge portion not covered by the separator, wherein the additional dummy layer may include: a first additional dummy layer separated from the dummy layer along the edge of the separator; and a second additional dummy layer disposed on the first additional dummy layer and electrically separated from the pattern portion along the edge of the separator.

In an embodiment, the display panel may further include: an encapsulation layer covering the light-emitting device and the sensing electrode and including a first inorganic layer, an organic layer, and a second inorganic layer sequentially stacked in a thickness direction; and a light control layer disposed on the encapsulation layer.

In an embodiment, the display panel may further include: a first inorganic layer covering the light-emitting device and the sensing electrode; a color filter layer disposed on the first inorganic layer; and a second inorganic layer disposed on the color filter layer.

In an embodiment, the light-emitting device may include a first light-emitting device, a second light-emitting device, and a third light-emitting device that emit different colors, and the color filter layer may include: a first color filter layer overlapping the first light-emitting device; a second color filter layer overlapping the second light-emitting device; and a third color filter layer overlapping the third light-emitting device.

In an embodiment, the display panel may further include an overcoating layer disposed on the second inorganic layer.

In an embodiment of the inventive concept, a display panel includes a transistor; a pixel defining layer having a light-emitting opening defined therein; a light-emitting device including a first electrode at least a center of which is not covered by the pixel defining layer, a second electrode electrically connected to the transistor and disposed on the first electrode in a region overlapping the light-emitting opening, and a light-emitting layer disposed between the first electrode and the second electrode; a separator disposed on the pixel defining layer and having a separating opening defined therein, overlapping the light-emitting opening, and having the second electrode disposed therein, the separating opening overlapping the light-emitting opening and the second electrode being disposed in the separating opening, and a sensing electrode including a pattern portion overlapping the separator and disposed on the separator and a bridge portion disposed between the pixel defining layer and the separator, wherein: the bridge portion is disposed to be spaced apart from the separating opening and partially covered by the separator; and the pattern portion is connected to a portion of the bridge portion not covered by the separator.

In an embodiment, the separator may include a first side surface defining the separating opening and a second side surface opposite to the first side surface, wherein an interior angle formed between the second side surface and an upper surface of the pixel defining layer may be smaller than an interior angle formed between the first side surface and the upper surface of the pixel defining layer.

In an embodiment, the separator may include a connection opening in which the separator on a portion of the bridge portion may be removed, a portion of an inner side surface of the separator defining the connection opening may correspond to the second side surface, and the pattern portion may be connected to the bridge portion through the connection opening.

In an embodiment, the separator may include a first separator and a second separator spaced apart from each other, a portion of the bridge portion may overlap the first separator, another portion of the bridge portion may overlap the second separator, a remaining portion of the bridge portion may not be covered by the first separator and the second separator, and the second side surface may correspond to an outer side surface of the second separator facing the first separator, wherein the interior angle formed between the second side surface and the upper surface of the pixel defining layer may be smaller than an interior angle formed between an outer side surface of the first separator facing the second side surface and the upper surface of the pixel defining layer.

In an embodiment, the pattern portion may be electrically separated from the second electrode along an edge of the separator.

In an embodiment, the display panel may further include a connection line electrically connecting the transistor to the second electrode, wherein the connection line may include a first connection part connected to the second electrode and spaced apart from the light-emitting opening in a plan view; and a second connection part connected to the transistor.

### BRIEF DESCRIPTION OF THE DRAWINGS

The accompanying drawings are included to provide a further understanding of the inventive concept, and are incorporated in and constitute a portion of this specification. The drawings illustrate embodiments of the inventive concept and, together with the description, serve to explain principles of the inventive concept. In the drawings:

FIG. 1 is a is a block diagram of a display device according to an embodiment of the inventive concept;

FIGS. 2A and 2B are equivalent circuit diagrams of pixels according to an embodiment of the inventive concept;

FIGS. 3A and 3B are plan views of a display panel according to an embodiment of the inventive concept;

FIGS. 4A to 4C are enlarged plan views illustrating some elements of the display panel in a display region according to an embodiment of the inventive concept;

FIG. 5 is an enlarged cross-sectional view illustrating a partial region of the display panel according to an embodiment of the inventive concept, which is taken along line I-I′ of FIG. 4B;

FIG. 6A is an enlarged cross-sectional view illustrating a partial region of the display panel according to an embodiment of the inventive concept, which corresponds to a region AA of FIG. 5;

FIG. 6B is an enlarged cross-sectional view illustrating a partial region of the display panel according to an embodiment of the inventive concept, which corresponds to a region BB of FIG. 5;

FIG. 7 is an enlarged cross-sectional view illustrating a partial region of a display panel according to an embodiment of the inventive concept;

FIG. 8 is a plan view illustrating some elements of the display panel according to an embodiment of the inventive concept;

FIG. 9 is an enlarged plan view illustrating a partial region of the display panel according to an embodiment of the inventive concept, which corresponds to a region CC of FIG. 8;

FIG. 10A is an enlarged plan view illustrating a partial region of the display panel according to an embodiment of the inventive concept, which corresponds to a region DD of FIG. 9;

FIG. 10B is an enlarged plan view illustrating some elements of the display panel in a display region according to an embodiment of the inventive concept;

FIG. 11 is an enlarged plan view illustrating a partial region of the display panel according to an embodiment of the inventive concept, which corresponds to a region EE of FIG. 10A;

FIG. 12A is an enlarged cross-sectional view illustrating a partial region of the display panel according to an embodiment of the inventive concept, which is taken along line II-II′ of FIG. 11;

FIG. 12B is an enlarged cross-sectional view illustrating a partial region of the display panel according to an embodiment of the inventive concept, which is taken along line III-III′ of FIG. 11;

FIG. 13 is an enlarged cross-sectional view illustrating a partial region of a display panel according to an embodiment of the inventive concept;

FIG. 14 is an enlarged plan view illustrating some elements of the display panel in a display region according to an embodiment of the inventive concept;

FIG. 15A is an enlarged cross-sectional view illustrating a partial region of a display panel according to an embodiment of the inventive concept, which is taken along line IV-IV′ of FIG. 14;

FIG. 15B is an enlarged cross-sectional view illustrating a partial region of the display panel according to an embodiment of the inventive concept, which is taken along line V-V′ of FIG. 14; and

FIG. 16 is an enlarged cross-sectional view illustrating a partial region of a display panel according to an embodiment of the inventive concept.

### DETAILED DESCRIPTION

In this specification, it will be understood that when an element (or region, layer, portion, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the present inventive concept. Similarly, the second element may also be referred to as the first element. The terms of a singular form include a plural form unless otherwise specified.

Terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

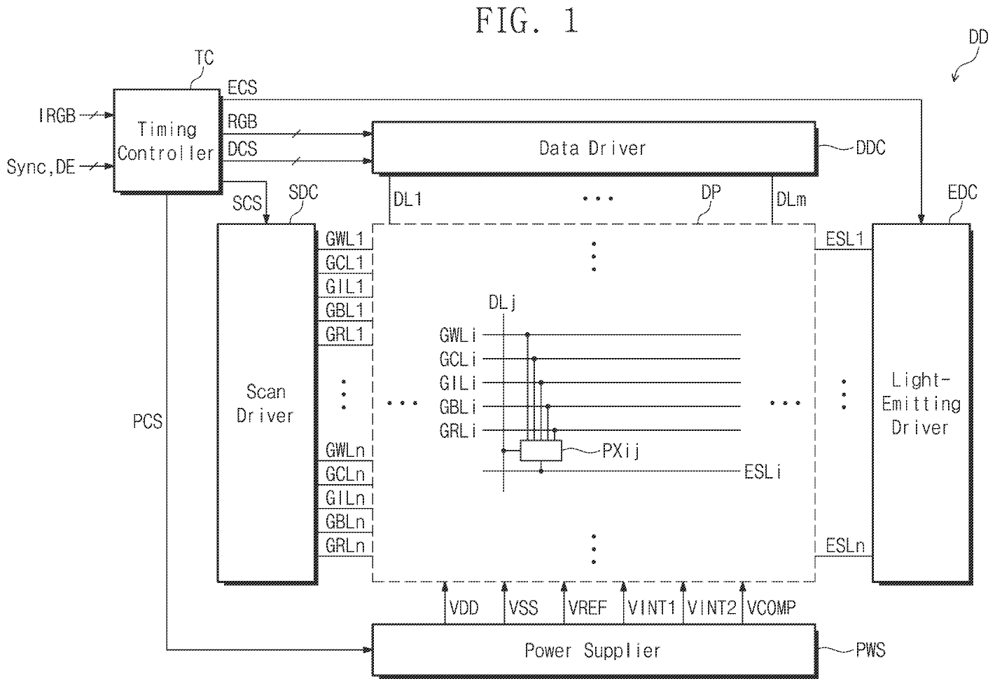

FIG. 1 is a block diagram of a display device according to an embodiment of the inventive concept.

Referring to FIG. 1, the display device DD may include a display panel DP, a panel driving unit SDC, EDC, and DDC, a power supplier PWS, and a timing controller TC. In this embodiment, the display panel DP is described as a light-emitting display panel. The light-emitting display panel may include an organic light-emitting display panel, an inorganic light-emitting display panel, or a quantum dot light-emitting display panel. In embodiments to be described later, an organic light-emitting display panel will be described in detail as an example. The panel driving unit may include a scan driver SDC, a light-emitting driver EDC, and a data driver DDC.

The display panel DP may include scan lines GWL1 to GWLn, GCL1 to GCLn, GIL1 to GILn, GBL1 to GBLn, and GRL1 to GRLn, light-emitting lines ESL1 to ESLn, and data lines DL1 to DLm. The display panel DP may include a plurality of pixels connected to the scan lines GWL1 to GWLn, GCL1 to GCLn, GIL1 to GILn, GBL1 to GBLn, and GRL1 to GRLn, the light-emitting lines ESL1 to ESLn, and the data lines DL1 to DLm (wherein m and n are integers greater than 0).

For example, a pixel PXij (i and j are integers greater than 0) located on an i-th horizontal line (or an i-th pixel row) and a j-th vertical line (or a j-th pixel column) may be connected to an i-th first scan line GWLi (or write scan line), an i-th second scan line GCLi (or compensation scan line), an i-th third scan line GILi (or first initialization scan line), an i-th fourth scan line GBLi (or second initialization scan line), an i-th fifth scan line GRLi (or reset scan line), a j-th data line DLj, and an i-th light-emitting line ESLi.

The pixel PXij may include a plurality of light-emitting devices, a plurality of transistors, and at least one capacitor. The pixel PXij may receive, through the power supplier PWS, a first power voltage VDD, a second power voltage VSS, a third power voltage VREF (or reference voltage), a fourth power voltage VINT1 (or first initialization voltage), a fifth power voltage VINT2 (or second initialization voltage), and a sixth power voltage VCOMP (or compensation voltage).

The voltage values of the first power voltage VDD and the second power voltage VSS are set so that current can flow through a light-emitting device so as to emit light. For example, the first power voltage VDD may be set to a higher voltage than the second power voltage VSS.

The third power voltage VREF may be a voltage for initializing a gate of a driving transistor included in the pixel PXij. The third power voltage VREF may be used to implement a predetermined gradation by using a voltage difference between a data signal and the third power voltage VREF. To this end, the third power voltage VREF may be set to a predetermined voltage within the voltage range of the data signal.

The fourth power voltage VINT1 may be a voltage for initializing a capacitor included in the pixel PXij. The fourth power voltage VINT1 may be set to a voltage lower than the third power voltage VREF. For example, the fourth power voltage VINT1 may be set to a voltage lower than a difference between the third power voltage VREF and a threshold voltage of the driving transistor. However, the embodiment of the inventive concept is not limited thereto.

The fifth power voltage VINT2 may be a voltage for initializing a cathode of the light-emitting device included in the pixel PXij. The fifth power voltage VINT2 may be set to a voltage lower than the first power voltage VDD or the fourth power voltage VINT1, or may be set to a voltage similar to or equal to the third power voltage VREF, but the embodiment of the inventive concept is not limited thereto, and the fifth power voltage VINT2 may be set to a voltage similar to or equal to the first power voltage VDD.

The sixth power voltage VCOMP may supply a predetermined current to the driving transistor when compensating for the threshold voltage of the driving transistor.

Meanwhile, FIG. 1 illustrates that the first to sixth power voltages VDD, VSS, VREF, VINT1, VINT2, and VCOMP are all supplied from the power supplier PWS, but the embodiment of the inventive concept is not limited thereto. For example, the first power voltage VDD and the second power voltage VSS are all supplied from the power supplier PWS regardless of the structure of the pixel PXij, and at least one of the third power voltage VREF, the fourth power voltage VINT1, the fifth power voltage VINT2 and the sixth power voltage VCOMP may not be supplied from the power supplier PWS according to the structure of the pixel PXij.

In an embodiment of the inventive concept, signal lines connected to the pixel PXij may be set in various ways according to a circuit structure of the pixel PXij.

The scan driver SDC may receive a first control signal SCS from the timing controller TC and, based on the first control signal SCS, supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The scan signal may be set to a voltage at which transistors that receive the scan signal may be turned on. For example, a scan signal supplied to a P-type transistor may be set to a logic low level and a scan signal supplied to an N-type transistor may be set to a logic high level. Hereinafter, the expression “a scan signal is supplied” may mean that the scan signal is supplied with a logic level that turns on a transistor which is controlled by the scan signal.

FIG. 1 illustrates, for the convenience of explanation, that the scan driver SDC is a single element, but the embodiment of the inventive concept is not limited thereto. According to an embodiment of the inventive concept, a plurality of scan drivers may be included to supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The light-emitting driver EDC may supply a light-emitting signal to the light-emitting lines ESL1 to ESLn based on a second control signal ECS. For example, the light-emitting signal may be sequentially supplied to the light-emitting lines ESL1 to ESLn.

Transistors connected to the light-emitting lines ESL1 to ESLn according to an embodiment of the inventive concept may include N-type transistors. In this case, the light-emitting signal supplied to the light-emitting lines ESL1 to ESLn may be set to a gate-on voltage. Transistors, which receive the light-emitting signal, may be turned off when the light-emitting signal is supplied, and in cases other than that, the transistors may be set to a state in which they are turned on.

The second control signal ECS may include a light-emitting start signal and clock signals, and the light-emitting driver EDC may be implemented as a shift register which sequentially generates and outputs the light-emitting signal in a pulse form by sequentially shifting the light-emitting start signal in a pulse form with the use of the clock signals.

The data driver DDC may receive a third control signal DCS and image data RGB from the timing controller TC. The data driver DDC may convert the image data RGB in digital form into an analog data signal (i.e., a data signal). The data driver DDC may supply a data signal to the data lines DL1 to DLm in response to the third control signal DCS.

The third control signal DCS may include a data enable signal, a horizontal start signal, a data clock signal, and the like to output valid data signals. For example, the data driver DDC may include a shift register configured to generate a sampling signal by shifting the horizontal start signal in synchronization with the data clock signal, a latch configured to latch the image data RGB in response to the sampling signal, a digital-to-analog converter (or decoder) configured to convert the latched image data (e.g., data in digital form) into data signals in analog form, and buffers (or amplifiers) configured to output the data signals to the data lines DL1 to DLm.

The power supplier PWS may supply the display panel DP with the first power voltage VDD, the second power voltage VSS, and the third power voltage VREF for driving the pixel PXij. In addition, the power supplier PWS may supply the display panel DP with at least one of the fourth power voltage VINT1, the fifth power voltage VINT2, or the sixth power voltage VCOMP.

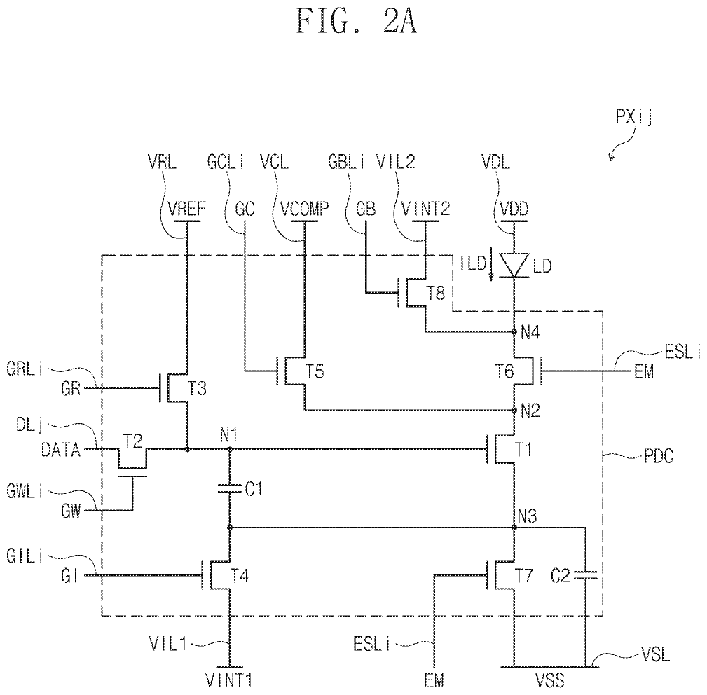

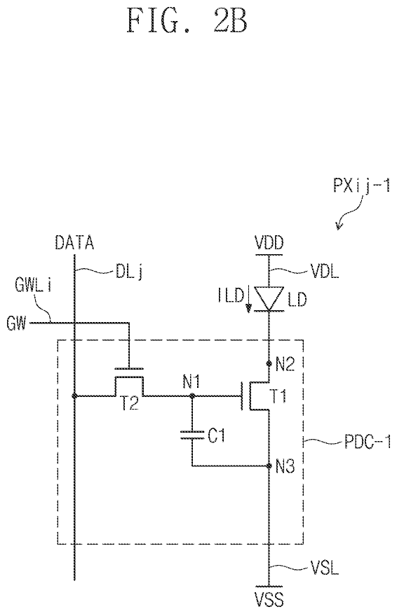

For example, the power supplier PWS may supply the display panel DP with the first power voltage VDD, the second power voltage VSS, the third power voltage VREF, the fourth power voltage VINT1, the fifth power voltage VINT2, and the sixth power voltage VCOMP respectively via a first power line VDL (see FIG. 2A), a second power line VSL (see FIG. 2A), a third power line VRL (or reference voltage line, see FIG. 2A), a fourth power line VIL1 (or first initialization voltage line, see FIG. 2A), a fifth power line VIL2 (or second initialization voltage line, see FIG. 2A), and a sixth power line VCL (or compensation voltage line, see FIG. 2A).

The power supplier PWS may be implemented as a power management integrated circuit, but the embodiment of the inventive concept is not limited thereto.

The timing controller TC may generate a first control signal SCS, a second control signal ECS, a third control signal DCS, and a fourth control signal PCS based on an input image data IRGB, a sync signal Sync (e.g., a vertical sync signal, a horizontal sync signal, etc.), a data enable signal DE, a clock signal, and the like. The first control signal SCS may be supplied to the scan driver SDC, the second control signal ECS may be supplied to the light-emitting driver EDC, the third control signal DCS may be supplied to the data driver DDC, and the fourth control signal PCS may be supplied to the power supplier PWS. The timing controller TC may rearrange the input image data so as to correspond to the arrangement of the pixels PXij in the display panel DP to generate image data RGB (or frame data).

Meanwhile, the scan driver SDC, the light-emitting driver EDC, the data driver DDC, the power supplier PWS, and/or the timing controller TC may be formed directly on the display panel DP or provided in the form of a separate driving chip and connected to the display panel DP. In addition, at least two of the scan driver SDC, the light-emitting driver EDC, the data driver DDC, the power supplier PWS, and the timing controller TC may be provided as one driving chip. For example, the data driver DDC and the timing controller TC may be embedded in one driving chip.

In the above, the display device DD according to an embodiment of the inventive concept has been described with reference to FIG. 1, but the display device according to this inventive concept is not limited thereto. More signal lines may be added or some signal lines may be omitted according to the configuration of the pixels. In addition, a connection relationship between one pixel and signal lines may be changed. When any one of the signal lines is omitted, another signal line may substitute for the omitted signal line.

FIGS. 2A and 2B are equivalent circuit diagrams of pixels according to an embodiment of the inventive concept. FIGS. 2A and 2B exemplarily illustrate the equivalent circuit diagrams of pixels PXij and PXij-1 connected to the i-th first scan line GWLi (hereinafter referred to as a write scan line) and connected to the j-th data line DLj (hereinafter referred to as a data line).

As illustrated in FIG. 2A, the pixel PXij includes a light-emitting device LD and a pixel driver PDC. The light-emitting device LD is connected between the first power line VDL and the pixel driver PDC.

The pixel driver PDC may be connected to a plurality of scan lines GWLi, GCLi, GILi, GBLi, and GRLi, a data line DLj, a light-emitting line ESLi, and a plurality of power voltage lines VDL, VSL, VIL1, VIL2, VRL, and VCL. The pixel driver PDC may include first to eighth transistors T1, T2, T3, T4, T5, T6, T7, and T8, a first capacitor C1, and a second capacitor C2. Hereinafter, as an example, all of the first to eighth transistors T1, T2, T3, T4, T5, T6, T7, and T8 will be described as N-type transistors. However, the embodiment of the inventive concept is not limited thereto, and some of the first to eighth transistors T1 to T8 may be N-type transistors and the others thereof may be P-type transistors, and all of the first to eighth transistors T1 to T8 may be P-type transistors, and the inventive concept is not limited to any one embodiment.

The gate of the first transistor T1 may be connected to a first node N1. The first electrode of the first transistor T1 may be connected to a second node N2, and the second electrode thereof may be connected to a third node N3. The first transistor T1 may be a driving transistor. The first transistor T1 may control a driving current ILD flowing from the first power line VDL to the second power line VSL via the light-emitting device LD in response to a voltage of the first node N1. In this case, the first power voltage VDD may be set to a voltage having a higher potential than the second power voltage VSS.

In this specification, the expression “a transistor and a signal line are electrically connected to each other, or a transistor and a transistor are electrically connected to each other” means that the source, drain, and gate of a transistor have an integral shape with the signal line or they are connected through a connection electrode.

The second transistor T2 may include a gate connected to the write scan line GWLi, a first electrode connected to the data line DLj, and a second electrode connected to the first node N1. The second transistor T2 may supply a data signal DATA to the first node N1 in response to a write scan signal GW transmitted through the write scan line GWLi. When the write scan signal GW is supplied to the write scan line GWLi, the second transistor T2 may be turned on to electrically connect the data line DLj to the first node N1.

The third transistor T3 may be connected between the first node N1 and the reference voltage line VRL. The first electrode of the third transistor T3 may receive the reference voltage VREF through the reference voltage line VRL and the second electrode of the third transistor T3 may be connected to the first node N1. In this embodiment, the gate of the third transistor T3 may receive a reset scan signal GR through the i-th fifth scan line GRLi (hereinafter referred to as a reset scan line). When the reset scan signal GR is supplied to the reset scan line GRLi, the third transistor T3 may be turned on to provide the reference voltage VREF to the first node N1.

The fourth transistor T4 may be connected between the third node N3 and the first initialization voltage line VIL1. The first electrode of the fourth transistor T4 may be connected to the third node N3, and the second electrode of the fourth transistor T4 may be connected to the first initialization voltage line VIL1 that provides the first initialization voltage VINT1. The fourth transistor T4 may be referred to as a first initialization transistor. The gate of the fourth transistor T4 may receive a first initialization scan signal GI through the i-th third scan line GILi (hereinafter referred to as a first initialization scan line). When the first initialization scan signal GI is supplied to the first initialization scan line GILi, the fourth transistor T4 may be turned on to supply the first initialization voltage VINT1 to the third node N3.

The fifth transistor T5 may be connected between the compensation voltage line VCL and the second node N2. The first electrode of the fifth transistor T5 may receive the compensation voltage VCOMP through the compensation voltage line VCL, and the second electrode of the fifth transistor T5 may be connected to the second node N2 to be electrically connected to the first electrode of the first transistor T1. The gate of the fifth transistor T5 may receive a compensation scan signal GC through the i-th second scan line GCLi (hereinafter referred to as a compensation scan line). When the compensation scan signal GC is supplied to the compensation scan line GCLi, the fifth transistor T5 may be turned on to provide the compensation voltage VCOMP to the second node N2, and during a compensation period, a threshold voltage of the first transistor T1 may be compensated.

The sixth transistor T6 may be connected between the first transistor T1 and the light-emitting device LD. Specifically, the gate of the sixth transistor T6 may receive a light-emitting signal EM through the i-th light-emitting line ESLi (hereinafter referred to as a light-emitting line). The first electrode of the sixth transistor T6 may be connected to the cathode of the light-emitting device LD through a fourth node N4, and the second electrode of the sixth transistor T6 may be connected to the first electrode of the first transistor T1 through the second node N2. The sixth transistor T6 may be referred to as a first light-emitting control transistor. When the light-emitting signal EM is supplied to the light-emitting line ESLi, the sixth transistor T6 may be turned on to electrically connect the light-emitting device LD and the first transistor T1.

The seventh transistor T7 may be connected between the second power line VSL and the third node N3. The first electrode of the seventh transistor T7 may be connected to the second electrode of the first transistor T1 through the third node N3, and the second electrode of the seventh transistor T7 may receive the second power voltage VSS through the second power line VSL. The gate of the seventh transistor T7 may be electrically connected to the light-emitting line ESLi. The seventh transistor T7 may be referred to as a second light-emitting control transistor. When the light-emitting signal EM is supplied to the light-emitting line ESLi, the seventh transistor T7 may be turned on to electrically connect the second electrode of the first transistor T1 and the second power line VSL to each other.

Meanwhile, in this embodiment, the sixth transistor T6 and the seventh transistor T7 are illustrated as being connected to the same light-emitting line ESLi and turned on by a same light-emitting signal EM, but this is illustrated as an example, and the sixth transistor T6 and the seventh transistor T7 may be independently turned on by different signals that are distinguished from each other. In addition, in the pixel driver PDC according to an embodiment of the inventive concept, any one of the sixth transistor T6 and the seventh transistor T7 may be omitted.

The eighth transistor T8 may be connected between the second initialization voltage line VIL2 and the fourth node N4. That is, the eighth transistor T8 may include: a gate connected to the i-th fourth scan line GBLi (hereinafter referred to as a second initialization scan line); a first electrode connected to the second initialization voltage line VIL2; and a second electrode connected to the fourth node N4. The eighth transistor T8 may be referred to as a second initialization transistor. The eighth transistor T8 may supply the second initialization voltage VINT2 to the fourth node N4 corresponding to the cathode of the light-emitting device LD in response to a second initialization scan signal GB transmitted through the second initialization scan line GBLi. The cathode of the light-emitting device LD may be initialized by the second initialization voltage VINT2.

Meanwhile, in this embodiment, some of the second to eighth transistors T2, T3, T4, T5, T6, T7, and T8 may be simultaneously turned on by a same scan signal. For example, the eighth transistor T8 and the fifth transistor T5 may be simultaneously turned on by a same scan signal. For example, the eighth transistor T8 and the fifth transistor T5 may receive a same compensation scan signal. The eighth transistor T8 and the fifth transistor T5 may be simultaneously turned on/off by a same compensation scan signal. In this case, the compensation scan line GCLi and the second initialization scan line GBLi may be provided substantially as a single scan line. Accordingly, the initialization of the cathode of the light-emitting device LD and the compensation of the threshold voltage of the first transistor T1 may be performed at the same time. However, this is illustrated as an example and the inventive concept is not limited to any one embodiment.

In addition, according to this inventive concept, the initialization of the cathode of the light-emitting device LD and the compensation of the threshold voltage of the first transistor T1 may be performed by applying a same power voltage. For example, the compensation voltage line VCL and the second initialization voltage line VIL2 may be provided substantially as a single power voltage line. In this case, the initialization operation of a cathode and the compensation operation of a driving transistor may be performed with one power voltage, and thus designing the driver may be simplified. However, this is illustrated as an example, and the inventive concept is not limited to any one embodiment.

The first capacitor C1 may be disposed between the first node N1 and the third node N3. The first capacitor C1 may store a difference voltage between the first node N1 and the third node N3. The first capacitor C1 may be referred to as a storage capacitor.

The second capacitor C2 may be disposed between the third node N3 and the second power line VSL. That is, one electrode of the second capacitor C2 may be connected to the second power line VSL that receives the second power voltage VSS, and the other electrode of the second capacitor C2 may be connected to the third node N3. The second capacitor C2 may store a charge corresponding to a voltage difference between the second power voltage VSS and the third node N3. The second capacitor C2 may be referred to as a hold capacitor. The second capacitor C2 may have a higher capacitance than the first capacitor C1. Accordingly, the second capacitor C2 may minimize a voltage change of the third node N3 in response to a voltage change of the first node N1.

In this embodiment, the light-emitting device LD may be connected to the pixel driver PDC through the fourth node N4. The light-emitting device LD may include an anode connected to the first power line VDL and a cathode connected to the fourth node N4. In this embodiment, the light-emitting device LD may be connected to the pixel driver PDC through the cathode. That is, in the pixel PXij according to this inventive concept, a connection node to which the light-emitting device LD and the pixel driver PDC are connected may be the fourth node N4, and the fourth node N4 may correspond to a connection node between the first electrode of the sixth transistor T6 and the cathode of the light-emitting device LD. Accordingly, the potential of the fourth node N4 may substantially correspond to the potential of the cathode of the light-emitting device LD.

Specifically, the anode of the light-emitting device LD may be connected to the first power line VDL to receive the first power voltage VDD which is a constant voltage and the cathode thereof may be connected to the first transistor T1 through the sixth transistor T6. That is, in this embodiment in which the first to eighth transistors T1 to T8 are N-type transistors, the potential of the third node N3 corresponding to the source of the first transistor T1, which is the driving transistor, may not be directly affected by the characteristics of the light-emitting device LD. Therefore, although the light-emitting device LD is deteriorated, an effect on the gate-source voltage (Vgs) of the transistors constituting the pixel driver PDC, particularly the driving transistor, may be reduced. That is, since the amount of change in driving current due to deterioration of the light-emitting device LD may be reduced, the afterimage defects of the display panel due to an increase in use time may be reduced and the lifetime of the display panel may be improved.

Alternatively, as illustrated in FIG. 2B, the pixel PXij-1 may include a pixel driver PDC-1 including two transistors T1 and T2 and one capacitor C1. The pixel driver PDC-1 may be connected to a light-emitting device LD, a write scan line GWLi, a data line DLj, and a second power line VSL. The pixel driver PDC-1 illustrated in FIG. 2B may correspond to the pixel driver PDC illustrated in FIG. 2A, from which the third to eighth transistors T3 to T8 and the second capacitor C2 are omitted.

Each of the first and second transistors T1 and T2 may be an N-type or P-type transistor. In this embodiment, each of the first and second transistors T1 and T2 will be exemplarily described as an N-type transistor.

The first transistor T1 may include a gate connected to a first node N1, a first electrode connected to a second node N2, and a second electrode connected to a third node N3. The second node N2 may be connected to the first power line VDL, via the light-emitting device LD and the third node N3 may be connected to the second power line VSL. The first transistor T1 is connected to the light-emitting device LD through the second node N2 and connected to the second power line VSL through the third node N3. The first transistor T1 may be a driving transistor.

The second transistor T2 may include a gate configured to receive the write scan signal GW through the write scan line GWLi, a first electrode connected to the data line DLj, and a second electrode connected to the first node N1. The second transistor T2 may supply the data signal DATA to the first node N1 in response to the write scan signal GW transmitted through the write scan line GWLi.

The capacitor C1 may include an electrode connected to the first node N1 and an electrode connected to the third node N3. The capacitor C1 may store the data signal DATA transmitted to the first node N1.

The light-emitting device LD may include an anode and a cathode. In this embodiment, the anode of the light-emitting device LD is connected to the first power line VDL, and the cathode is connected to the pixel driver PDC-1 through the second node N2. In this embodiment, the cathode of the light-emitting device LD may be connected to the first transistor T1. The light-emitting device LD may emit light in response to the amount of current flowing through the first transistor T1 of the pixel driver PDC-1.

In this embodiment in which the first and second transistors T1 and T2 are N-type transistors, the second node N2 to which the cathode of the light-emitting device LD and the pixel driver PDC-1 are connected may correspond to the drain of the first transistor T1. That is, it is possible to prevent a change in the gate-source voltage (Vgs) of the first transistor T1 due to a deterioration of the light-emitting device LD. Accordingly, since the amount of change in driving current due to deterioration of the light-emitting device LD may be reduced, the afterimage defects of the display panel due to an increase in use time may be reduced and the lifetime of the display panel may be improved.

Meanwhile, FIGS. 2A and 2B illustrate the circuits for the pixel drivers PDC and PDC-1 according to an embodiment of the inventive concept, and as long as the circuits are connected to the cathode of the light-emitting device LD, the number or arrangement relationship of transistors and the number or arrangement relationship of capacitors may be designed in various ways and the inventive concept is not limited to any one embodiment.

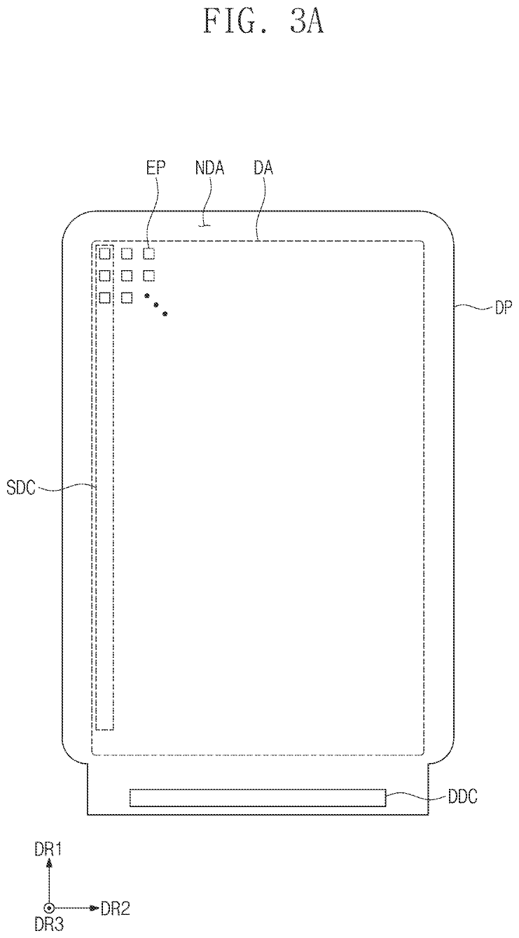

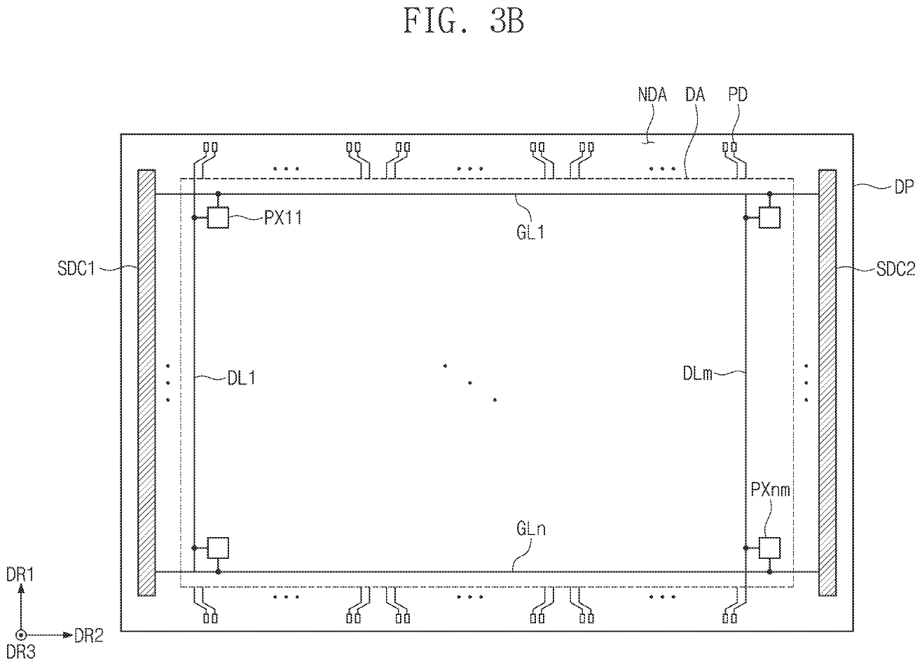

FIGS. 3A and 3B are plan views of a display panel according to an embodiment of the inventive concept. In each of FIGS. 3A and 3B, some elements are omitted, and for the convenience of description, some elements mounted on the display panel DP are illustrated together.

Referring to FIG. 3A, the display panel DP according to an embodiment of the inventive concept may include a display region DA and a peripheral region NDA (or non-display region). The display region DA may include a plurality of emitting parts EP.

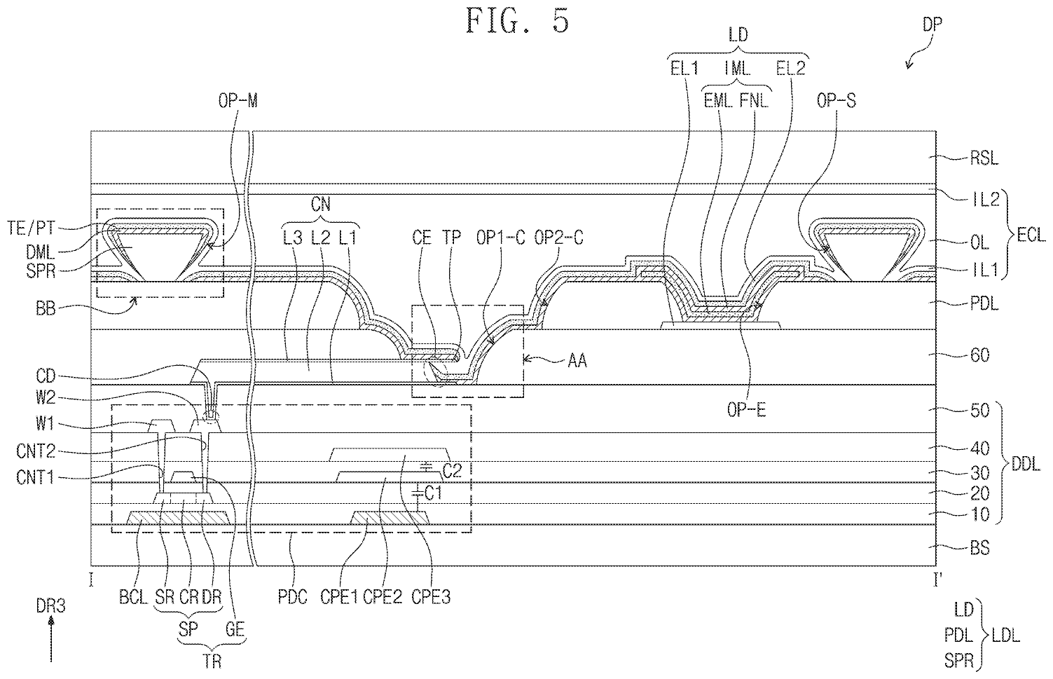

The emitting parts EP may be regions in which light is emitted by the pixels PXij (see FIG. 1), respectively. Specifically, each of the emitting parts EP may correspond to a light-emitting opening OP-E (see FIG. 5) which will be described later.

The peripheral region NDA may be disposed adjacent to the display region DA. In this embodiment, the peripheral region NDA is illustrated having a shape surrounding the edge of the display region DA. However, this is illustrated as an example, and the peripheral region NDA may be disposed on one side of the display region DA or may be omitted, and the inventive concept is not limited to any one embodiment.

In this embodiment, the scan driver SDC and the data driver DDC may be mounted on the display panel DP. In an embodiment of the inventive concept, the scan driver SDC may be disposed in the display region DA, and the data driver DDC may be disposed in the peripheral region NDA. In a plan view, the scan driver SDC may overlap at least a portion of the plurality of pixels disposed in the display region DA. As the scan driver SDC is disposed in the display region DA, the area of the peripheral region NDA may be reduced compared to a case in which the scan driver is disposed in the peripheral region, and the display device DD having a narrow bezel (see FIG. 1) may be easily implemented. In an embodiment, the scan driver SDC may overlap some of the plurality of emission parts EP.

Meanwhile, unlike what is illustrated in FIG. 3A, the scan driver SDC may be provided in two regions. The two regions of the scan driver SDC may be disposed to be spaced apart from each other on both sides of the display panel DP with the center of the display region DA interposed therebetween. Alternatively, the scan driver SDC may be provided in more than two regions, and the inventive concept is not limited to any one embodiment.

Meanwhile, FIG. 3A illustrates an example of a display panel in which the data driver is disposed in the peripheral region NDA. However, the data driver DDC may be disposed in the display region DA. In this case, some pixels disposed in the display region DA may overlap the data driver DDC in a plan view. In an embodiment, some of the emission parts may overlap the scan driver and/or the data driver.

In an embodiment of the inventive concept, the data driver DDC may be provided in the form of a separate driving chip and connected to the display panel DP. However, this is described as an example, and the data driver DDC may be formed through the same process as the scan driver SDC so as to constitute the display panel DP, and the inventive concept is not limited to any one embodiment.

As illustrated in FIG. 3B, the display panel DP may have a shape in which a length corresponding to the first direction DR1 is less than a length corresponding to the second direction DR2. In this embodiment, the display panel DP may include a plurality of scan drivers SDC1 and SDC2. The scan drivers SDC1 and SDC2 are illustrated as including a first scan driver SDC1 and a second scan driver SDC2 spaced apart from each other in the second direction DR2.

The first scan driver SDC1 may be connected to some of the scan lines GL1 to GLn, and the second scan driver SDC2 may be connected to other scan lines GL1 to GLn. For example, the first scan driver SDC1 may be connected to odd-numbered scan lines among the scan lines GL1 to GLn, and the second scan driver SDC2 may be connected to even-numbered scan lines among the scan lines GL1 to GLn.

FIG. 3B illustrates pads PD of the data lines DL1 to DLm for ease of description. The pads PD may be defined at ends of the data lines DL1 to DLm. The data lines DL1 to DLm may be connected to the data driver DDC (see FIG. 3A) through the pads PD.

According to this inventive concept, the pads PD may be arranged at positions spaced apart from each other in the peripheral region NDA with the display region DA interposed therebetween. For example, some of the pads PD may be disposed on the upper side, that is, on the side adjacent to the first scan line GL1 among the scan lines GL1 to GLn, and other pads PD may be disposed on the lower side, that is, on the side adjacent to the last scan line GLn among the scan lines GL1 to GLn. In this embodiment, pads PD connected to odd-numbered data lines among the data lines DL1 to DLm may be disposed on the upper side, and pads PD connected to even-numbered data lines among the data lines DL1 to DLm may be disposed on the lower side.

Although not illustrated, the display panel DP may include a plurality of upper data drivers connected to the pads PD disposed on the upper side and/or a plurality of lower data drivers connected to the pads PD disposed on the lower side. However, this is described as an example, and the display panel DP may include one upper data driver connected to the pads PD disposed on the upper side and/or one lower data driver connected to the pads PD disposed on the lower side. That is, the pads PD according to an embodiment of the inventive concept may be disposed on only one side of the display panel DP and connected to a single data driver, and the inventive concept is not limited to any one embodiment.

In addition, as described above with reference to FIG. 3A, in the display panel DP of FIG. 3B, the scan driver and/or the data driver may be disposed in the display region DA, and accordingly, some of the pixels disposed in the display region DA may overlap the scan driver and/or the data driver in a plan view.

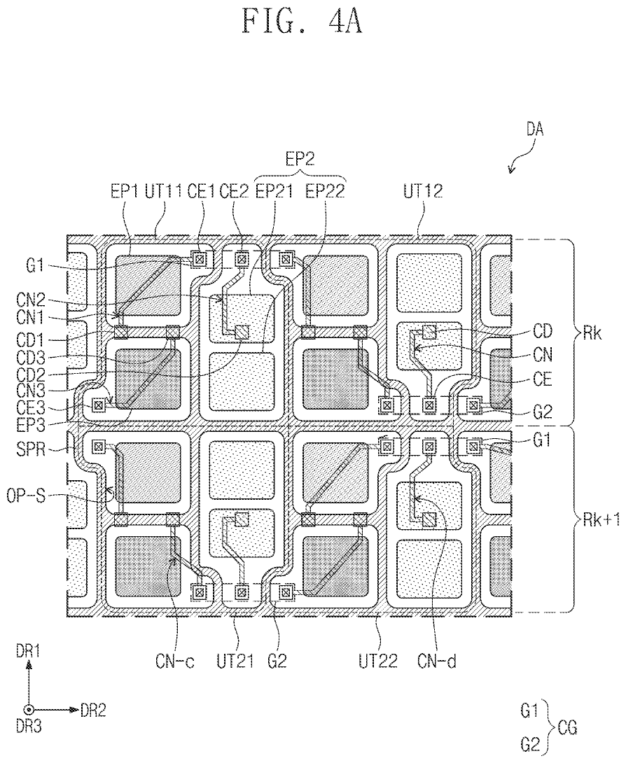

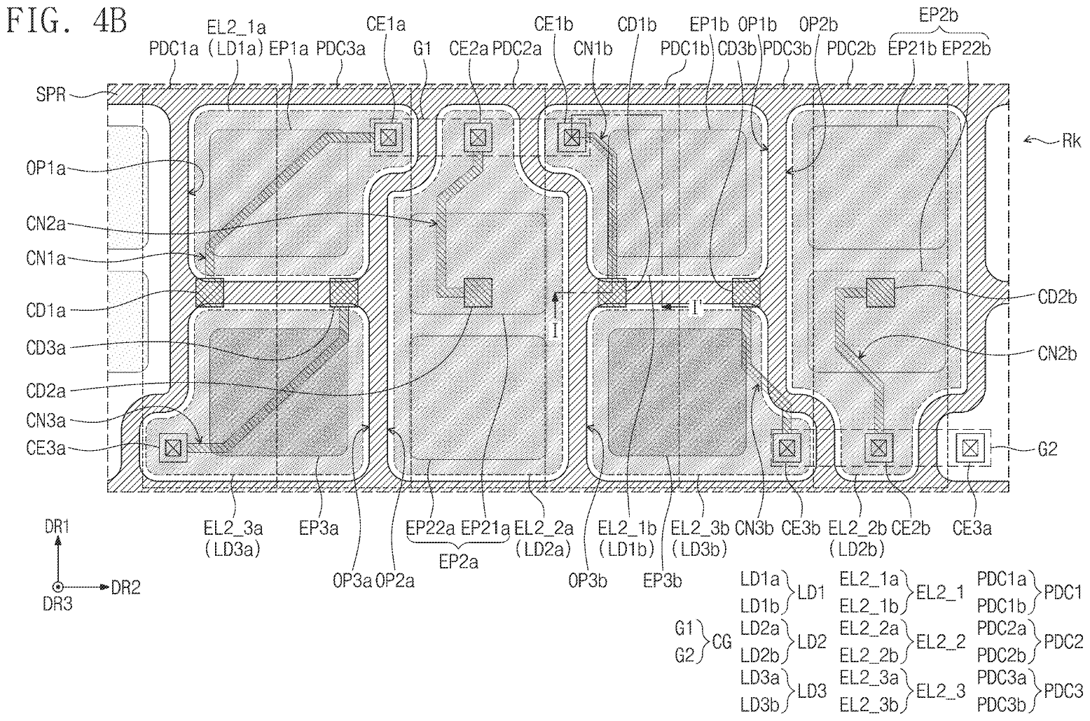

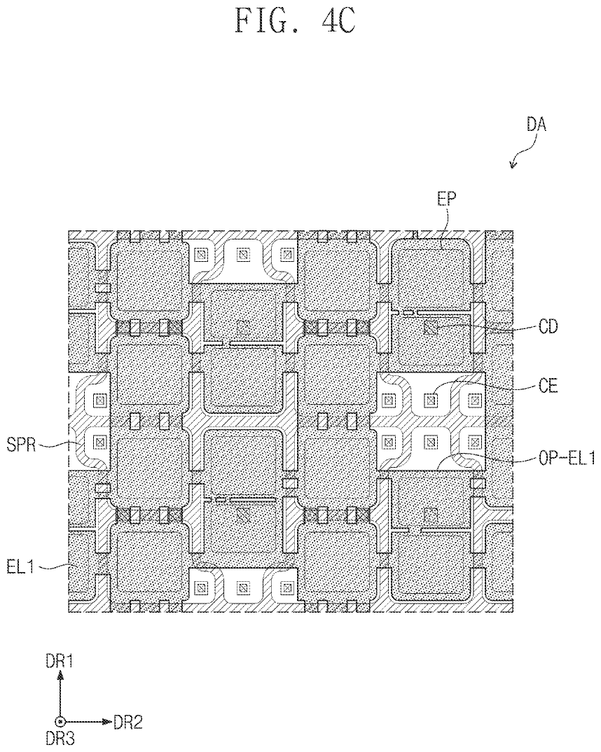

FIGS. 4A to 4C are enlarged plan views illustrating some elements of the display panel in a display region according to an embodiment of the inventive concept. FIG. 4A illustrates a region in which a total of four light-emitting units UT11, UT12, UT21, and UT22 are disposed in 2 rows and 2 columns, and FIG. 4B is an enlarged view illustrating a partial region of FIG. 4A. In FIG. 4C, some of the elements illustrated in FIG. 4A are omitted or emphasized. Hereinafter, the light-emitting units UT11, UT12, UT21, and UT22 will be described in detail with reference to FIGS. 4A to 4C.

The emitting parts of a first row Rk include emitting parts EP1, EP2, and EP3 constituting a first row first column light-emitting unit UT11 and a first row second column light-emitting unit UT12, and the emitting parts of a second row Rk+1 include emitting parts EP1, EP2, and EP3 constituting a second row first column light-emitting unit UT21 and a second row second column light-emitting unit UT22. FIGS. 4A to 4C illustrate, among the elements of the display panel DP (see FIG. 1), a separator SPR, a plurality of emitting parts EP1, EP2, and EP3 each disposed in a region partitioned by the separator SPR, connection lines CN1, CN2, and CN3, an anode EL1 (or a first electrode), and cathodes EL2_1, EL2_2, and EL2_3 (or second electrodes).

Each of the emitting parts EP1, EP2, and EP3 may be regions in which light emitted by the light-emitting device LD (see FIG. 2A or 2B) is displayed and correspond to a unit constituting an image displayed in the display panel DP (see FIG. 1).

The emitting parts EP1, EP2, and EP3 may include a first emitting part EP1, a second emitting part EP2, and a third emitting part EP3. The first emitting part EP1, the second emitting part EP2, and the third emitting part EP3 may display light of different colors. For example, the first emitting part EP1 may display red light, the second emitting part EP2 may display blue light, and the third emitting part EP3 may display green light, but the combination of colors is not limited thereto. In addition, at least two of the emitting parts EP1, EP2, and EP3 may emit light of a same color. For example, all of the first to third emitting parts EP1, EP2, and EP3 may emit blue light or white light.

Meanwhile, among the emitting parts EP1, EP2, and EP3, the second emitting part EP2 may include two sub-emitting parts EP21 (e.g., EP21a and EP21b) and EP22 (e.g., EP22a and EP22b) spaced apart from each other in the first direction DR1. However, this is illustrated as an example, and the second emitting part EP2 may be provided in one pattern having an integral shape like the other emitting parts EP1 and EP3, and at least any one of the other emitting parts EP1 and EP3 may include sub-emitting parts, and the inventive concept is not limited to any one embodiment.

In this embodiment, the emitting parts of the first row Rk may include the first row first column light-emitting units UT11 and the first row second column light-emitting units UT12 that are repeatedly arranged along the second direction DR2. The emitting parts of the second row Rk+1 may include the second row first column light-emitting units UT21 and the second row second column light-emitting units UT22 are repeatedly arranged along the second direction DR2. The emitting parts of the second row Rk+1 may have a shape in which the emitting parts of the first row Rk are shifted one column in the second direction DR2. That is, the first row first column light-emitting unit UT11 and the second row second column light-emitting unit UT22 may have a same shape (hereinafter referred to as 1-1st, 2-1st, and 3-1st emitting parts EP1a, EP2a, and EP3a), and the first row second column light-emitting unit UT12 and the second row first column light-emitting unit UT21 may have a same shape (hereinafter referred to as 1-2nd, 2-2nd, and 3-2nd emitting parts EP1b, EP2b, and EP3b).

FIG. 4B is an enlarged view illustrating two light-emitting units disposed in the first row Rk. Each light-emitting unit may include a first emitting part EP1a or EP1b and a third emitting part EP3a or EP3b spaced apart from each other in the first direction DR1, and a second emitting part EP2a or EP2b spaced apart from the first and third emitting parts EP1a or EP1b, EP3a or EP3b in the second direction DR2 may be disposed in each light-emitting unit. The 2-1st emitting part EP2a of each of the first row first column light-emitting unit UT11 and the second row second column light-emitting unit UT22 may be disposed to face the 3-1st emitting part EP3a more closely than the 1-1st emitting part EP1a, and the 2-2nd emitting part EP2b of each of the first row second column light-emitting unit UT12 and the second row first column light-emitting unit UT21 may be disposed to face the 1-2nd emitting part EP1b more closely than the 3-2nd emitting part EP3b. That is, in a same row and a same column, the 2-1st emitting part EP2a disposed to face the 3-1st emitting part EP3a more closely and the 2-2nd emitting part EP2b disposed to face the 1-2nd emitting part EP1b more closely may be arranged repeatedly.

For easy description, FIG. 4B illustrates a plurality of cathodes EL2_1a, EL2_2a, EL2_3a, EL2_1b, EL2_2b, and EL2_3b included in the two light-emitting units disposed in the first row Rk, a plurality of pixel drivers PDC1a, PDC2a, PDC3a, PDC1b, PDC2b, and PDC3b, and a plurality of connection lines CN1a, CN2a, CN3a, CN1b, CN2b, and CN3b.

The cathodes EL2_1a, EL2_2a, EL2_3a, EL2_1b, EL2_2b, and EL2_3b may be electrically disconnected from each other by being separated from each other in regions adjacent to the separator SPR. A plurality of separating openings OP-S may be formed in the separator SPR, and each of the cathodes EL2_1a, EL2_2a, EL2_3a, EL2_1b, EL2_2b, and EL2_3b may be disposed in each separating opening OP-S as an isolated pattern. Each of the cathodes EL2_1a, EL2_2a, EL2_3a, EL2_1b, EL2_2b, and EL2_3b may not be connected to adjacent cathodes. Accordingly, the arrangement and shape of the cathodes EL2_1a, EL2_2a, EL2_3a, EL2_1b, EL2_2b, and EL2_3bmay have the same arrangement and the same shape as the separating openings OP-S of the separator SPR.

1-1st to 3-1st separating openings OP1a, OP2a, and OP3a and 1-2nd to 3-2nd separating openings OP1b, OP2b, and OP3b may be formed in the separator SPR.

It may be considered that, as the 1-1st to 3-1st cathodes EL2_1a, EL2_2a, and EL2_3a are respectively disposed to be separated from each other in the 1-1st to 3-1st separating openings OP1a, OP2a, and OP3a, 1-1st to 3-1st light-emitting devices LD1a, LD2a, and LD3a respectively including the 1-1st to 3-1st cathodes EL2_1a, EL2_2a, and EL2_3a are also disposed to correspond to the 1-1st to 3-1st separating openings OP1a, OP2a, and OP3a. The 1-1st to 3-1st light-emitting devices LD1a, LD2a, and LD3a may respectively provide the 1-1st to 3-1st emitting parts EP1a, EP2a, and EP3a.

It may be considered that, as the 1-2nd to 3-2nd cathodes EL2_1b, EL2_2b, and EL2_3b are respectively disposed to be separated from each other in the 1-2nd to 3-2nd separating openings OP1b, OP2b, and OP3b, 1-2nd to 3-2nd light-emitting devices LD1b, LD2b, and LD3b respectively including the 1-2nd to 3-2nd cathodes EL2_1b, EL2_2b, and EL2_3b are also disposed to correspond to the 1-2nd to 3-2nd separating openings OP1b, OP2b, and OP3b. The 1-2nd to 3-2nd light-emitting devices LD1b, LD2b, and LD3b may respectively provide the 1-2nd to 3-2nd emitting parts EP1b, EP2b, and EP3b. The 2-1st light-emitting device LD2a and the 2-2nd light-emitting device LD2b may be respectively referred to as a second light-emitting device and a fourth light-emitting device.

One light-emitting unit may include: 1-1st to 3-1st light-emitting devices LD1a, LD2a, and LD3a respectively including the 1-1st to 3-1st cathodes EL2_1a, EL2_2a, and EL2_3a; 1-1st to 3-1st pixel drivers PDC1a, PDC2a, and PDC3a; and 1-1st to 3-1st connection lines CN1a, CN2a, and CN3a. Another adjacent light-emitting unit may include: 1-2nd to 3-2nd light-emitting devices LD1b, LD2b, and LD3brespectively including 1-2nd to 3-2nd cathodes EL2_1b, EL2_2b, and EL2_3b; 1-2nd to 3-2nd pixel drivers PDC1b, PDC2b, and PDC3b; and 1-2nd to 3-2nd connection lines CN1b, CN2b, and CN3b. However, this is illustrated as an example, and the number and arrangement of light-emitting units may be designed in various ways and are not limited to any one embodiment.

The 1-1st to 3-1st pixel drivers PDC1a, PDC2a and PDC3a and the 1-2nd to 3-2nd pixel drivers PDC1b, PDC2b and PDC3b are respectively connected to the 1-1st to 3-1st light-emitting devices LD1a, LD2a, and LD3a constituting the 1-1st to 3-1st emitting parts EP1a, EP2a, and EP3a and the 1-2nd to 3-2nd light-emitting devices LD1b, LD2b, and LD3b constituting the 1-2nd to 3-2nd emitting parts EP1b, EP2b, and EP3b. In this specification, the expression “being connected” includes not only being physically connected by a direct contact, but also being electrically connected.

Each region, in which the pixel drivers PDC1a, PDC2a, PDC3a, PDC1b, PDC2b, and PDC3b illustrated in FIG. 4B are disposed in a plan view, may correspond to a unit in which transistor and capacitor elements constituting the pixel drivers PDC or PDC-1 (see FIG. 2A or 2B) for driving the light-emitting device LD (see FIG. 2A or 2B) of the pixel are repeatedly arranged. In this embodiment, the 1-1st, 3-1st, and 2-1st pixel drivers PDC1a, PDC3a, and PDC2a may be sequentially disposed along the second direction DR2, and the 1-2nd, 3-2nd and 2-2nd pixel drivers PDC1b, PDC3b, and PDC2b may also be sequentially disposed along the second direction DR2. The arrangement of the pixel drivers PDC1a, PDC2a, PDC3a, PDC1b, PDC2b, and PDC3b may be designed independently of the positions or shapes of the emitting parts EP1a, EP2a, EP3a, EP1b, EP2b, and EP3b.

For example, the 1-1st to 3-1st pixel drivers PDC1a, PDC2a, and PDC3a may be designed to be disposed at a position different from a position at which the 1-1st to 3-1st separating openings OP1a, OP2a, and OP3a of the separator SPR, that is, the 1-1st to 3-1st cathodes EL2_1a, EL2_2a, and EL2_3a are disposed, or may be designed to have an area of a shape different from the shape of the 1-1st to 3-1st cathodes EL2_1a, EL2_2a, and EL2_3a. Alternatively, the 1-1st to 3-1st pixel drivers PDC1a, PDC2a, and PDC3a may be designed to be disposed to respectively overlap the positions at which the 1-1st to 3-1st emitting parts EP1a, EP2a, and EP3a exist and may be designed to have a shape having an area similar to that of the 1-1st to 3-1st separating openings OP1a, OP2a, and OP3a of the separator SPR, for example, the 1-1st to 3-1st cathodes EL2_1a, EL2_2a, and EL2_3a.

In this embodiment, each of the pixel drivers PDC1a, PDC2a, PDC3a, PDC1b, PDC2b, and PDC3b is illustrated in a rectangular shape, the emitting parts EP1a, EP2a, EP3a, EP1b, EP2b, and EP3b are arranged in a form different from that of the pixel drivers PDC1a, PDC2a, PDC3a, PDC1b, PDC2b, and PDC3b, and the cathodes EL2_1a, EL2_2a, EL2_3a, EL2_1b, EL2_2b, and EL2_3b are illustrated in an atypical shape in which they are respectively disposed to overlap the emitting parts EP1a, EP2a, EP3a, EP1b, EP2b, and EP3b.

Accordingly, as illustrated in FIG. 4B, the 1-1st pixel driver PDC1a may be disposed to partially overlap the 1-1st emitting part EP1a, the 3-1st emitting part EP3a, and another adjacent light-emitting unit. The 3-1st pixel driver PDC3a may be disposed to overlap the 1-1st emitting part EP1a, the 2-1st emitting part EP2a, and the 3-1st emitting part EP3a. The 2-1st pixel driver PDC2a may be disposed to overlap the 2-1st emitting part EP2a. The 1-2nd to 3-2nd pixel drivers PDC1b, PDC2b, and PDC3b may also be disposed similarly to the 1-1st to 1-3rd pixel drivers PDC1a, PDC2a, and PDC3a. Meanwhile, this is illustrated as an example, and the positions of the pixel drivers PDC1a, PDC2a, PDC3a, PDC1b, PDC2b, and PDC3b may be designed to have various shapes and arrangements independently of the emitting parts EP1a, EP2a, EP3a, EP1b, EP2b, and EP3b, and the inventive concept is not limited to any one embodiment.

A plurality of connection lines CN may be disposed to be spaced apart from each other. Each of the connection lines CN may connect the pixel driver PDC or PDC-1 (see FIG. 2A or 2B) and the light-emitting device LD (see FIG. 2A or 2B) to each other. Specifically, each of the connection lines CN may correspond to a node (see N4 of FIG. 2A or N2 of FIG. 2B) at which the light-emitting device LD (see FIG. 2A or 2B) is connected to the pixel driver PDC or PDC-1 (see FIG. 2A or 2B).

Each of the connection lines CN may include a first connection part CE (hereinafter referred to as an emission connection part) and a second connection part CD (hereinafter referred to as a driver connection part). The emission connection part CE may be provided on one side of the connection line CN and the driver connection part CD may be provided on the other side of the connection line CN.

The driver connection part CD may be a portion of the connection line CN connected to the pixel driver PDC or PDC-1 (see FIG. 2A or 2B). In this embodiment, the driver connection part CD is connected to one electrode of a transistor constituting the pixel driver PDC or PDC-1 (see FIG. 2A or 2B). Specifically, the driver connection part CD may be connected to the drain of the sixth transistor T6 illustrated in FIG. 2A or the drain of the first transistor T1 illustrated in FIG. 2B. Accordingly, the position of the driver connection part CD may correspond to the position of a transistor (see TR in FIG. 5) of the pixel driver PDC or PDC-1 (see FIG. 2A or 2B) which is physically connected to the connection line CN.

The emission connection part CE may be a portion of the connection line CN connected to the light-emitting device LD (see FIG. 2A or 2B). In this embodiment, in the emission connection part CE, the connection line CN may be connected to the cathodes EL2_1a, EL2_2a, EL2_3a, EL2_1b, EL2_2b, and EL2_3b.

One light-emitting unit may include first to third connection lines CN1, CN2, and CN3. The first connection line CN1 connects the first light-emitting device LD1, which forms the first emitting part EP1, to the first pixel driver PDC1, the second connection line CN2 connects the second light-emitting device LD2, which forms the second emitting part EP2, to the second pixel driver PDC2, and the third connection line CN3 connects the third light-emitting device LD3, which forms the third emitting part EP3, to the third pixel driver PDC3.

Specifically, the first to third connection lines CN1, CN2, and CN3 respectively connect the first to third cathodes EL2_1, EL2_2, and EL2_3 respectively included in the first to third light-emitting devices LD1, LD2, and LD3 to the first to third pixel drivers PDC1, PDC2, and PDC3. The first connection line CN1 may include a first driver connection part CD1 connected to the first pixel driver PDC1 and a first emission connection part CE1 connected to the first cathode EL2_1. The second connection line CN2 may include a second driver connection part CD2 connected to the second pixel driver PDC2 and a second emission connection part CE2 connected to the second cathode EL2_2. The third connection line CN3 may include a third driver connection part CD3 connected to the third pixel driver PDC3 and a third emission connection part CE3 connected to the third cathode EL2_3.

The first to third driver connection parts CD1 (e.g., CD1a and CD1b), CD2 (e.g., CD2a and CD2b), and CD3 (e.g., CD3a and CD3b) may be aligned along the second direction DR2. As described above, the first to third driver connection parts CD1, CD2, and CD3 may respectively correspond to positions of connection transistors constituting the first to third pixel drivers PDC1, PDC2, and PDC3. In one pixel, a connection transistor may be a transistor including a connection node as one electrode to which the pixel driver PDC or PDC-1 (see FIG. 2A or 2B) and the light-emitting device LD (see FIG. 2A or 2B) are connected. For example, the connection transistor may correspond to the sixth transistor T6 of FIG. 2A or the first transistor T1 of FIG. 2B. According to this inventive concept, processes may be simplified and costs may be reduced by designing the pixel driver identically for all pixels regardless of the shape or size of the emitting part and light-emitting colors.

In this embodiment, the first to third emission connection parts CE1, CE2, and CE3 may be disposed at positions that do not overlap the emitting parts EP1, EP2, and EP3 in a plan view. Since the emission connection part CE of the connection line CN is a portion to which the light-emitting device LD (see FIG. 2A or 2B) is connected and in which a tip part TP (see FIG. 5) is disposed, the emission connection part CE of the connection line CN is provided in a position that does not overlap the light-emitting opening OP-E (see FIG. 5). That is, the separating openings OP-S of the separator SPR may include regions protruding from the emitting parts EP1, EP2, and EP3 toward the emission connection part CE in a plan view, and the emission connection parts CE1, CE2, and CE3 may be provided in the protruding regions. Accordingly, the cathodes EL2_1, EL2_2, and EL2_3 may have protruding regions corresponding to the protruding regions of the separating openings OP-S and be connected to the connection lines CN1, CN2, and CN3 at the protruding regions in which the emission connection parts CE1, CE2, and CE3 are disposed. Accordingly, it is possible to provide an emission connection part which may be connected to the connection line without reducing a light-emitting area of an emitting part.

As illustrated in FIG. 4B, each of the 1-1st to 3-1st separating openings OP1a, OP2a, and OP3a and the 1-2nd to 3-2nd separating openings OP1b, OP2b, and OP3bmay include protruding regions. In the protruding regions of the 1-1st to 3-1st separating openings OP1a, OP2a, and OP3a, the 1-1st emission connection part CE1aof the 1-1st connection line CN1a, the 2-1st emission connection part CE2a of the 2-1st connection line CN2a, and the 3-1 emission connection part CE3a of the 3-1 connection line CN3a may be disposed. In the protruding regions of the 1-2nd to 3-2nd separating openings OP1b, OP2b, and OP3b, the 1-2nd emission connection part CE1b of the 1-2nd connection line CN1b, the 2-2nd emission connection part CE2b of the 2-2nd connection line CN2b, and the 3-2nd emission connection part CE3b of the 3-2nd connection line CN3b may be disposed.

The 1-1st emission connection part CE1a may be disposed to be spaced apart from the 1-1st emitting part EP1a in the second direction DR2, and the 1-2nd emission connection part CE1b may be disposed to be spaced apart from the 1-2nd emitting part EP1b in a direction opposite to the second direction DR2. The 2-1st emission connection part CE2a may be disposed to be spaced apart from the 2-1st emitting part EP2a in the first direction DR1, and the 2-2nd emission connection part CE2b may be disposed to be spaced apart from the 2-2nd emitting part EP2b in a direction opposite to the first direction DR1. The 3-1st emission connection part CE3a may be disposed to be spaced apart from the 3-1st emitting part EP3a in a direction opposite to the second direction DR2, and the 3-2nd emission connection part CE3b may be disposed to be spaced apart from the 3-2nd emitting part EP3b in the second direction DR2.

In this embodiment, the emission connection parts CE may be disposed adjacent to each other to form contact groups CG. The contact groups CG may include first subgroups G1 and second subgroups G2.

As the 1-1st separating opening OP1a and the 1-2nd separating opening OP1bare disposed with the 2-1st separating opening OP2a interposed therebetween, each of the protruding region of the 1-1st separating opening OP1a and the protruding region of the 1-2nd separating opening OP1b may be disposed to protrude toward the protruding region of the 2-1st separating opening OP2a. Accordingly, the 1-1st emission connection part CE1a and the 2-1st emission connection part CE2a disposed in one light-emitting unit and the 1-2nd emission connection part CE1b disposed in an adjacent light-emitting unit may be provided to be arranged in the second direction DR2 and may constitute a first subgroup G1.

As the 3-2nd separating opening OP3b and the 3-1st separating opening OP3aare disposed with the 2-2nd separating opening OP2b interposed therebetween, each of the protruding region of the 3-2nd separating opening OP3b and the protruding region of the 3-1st separating opening OP3a may be disposed to protrude toward the protruding region of the 2-2nd separating opening OP2b. Accordingly, the 3-2nd emission connection part CE3b and the 2-2nd emission connection part CE2b disposed in one light-emitting unit and the 3-1st emission connection part CE3a disposed in an adjacent light-emitting unit may be provided to be arranged in the second direction DR2 and may constitute a second subgroup G2.

In this embodiment, the shape and arrangement form of connection lines CN-c disposed in the second row first column light-emitting unit UT21 may be the same as the 1-2nd to 3-2nd connection lines CN1b, CN2b, and CN3b disposed in the first row second column light-emitting unit UT12. Similarly, the shape and arrangement form of connection lines CN-d disposed in the second row second column light-emitting unit UT22 may be the same as the 1-1st to 3-1st connection lines CN1a, CN2a, and CN3a disposed in the first row first column light-emitting unit UT11. The arrangement of the emission connection parts CE in the second row Rk+1 may have a shape in which the arrangement of the emission connection parts CE in the first row Rk is shifted one column in the second direction DR2.

Accordingly, as illustrated in FIG. 4A, the first subgroups G1 and the second subgroups G2 may be alternately arranged in each of the row direction and the column direction. A first subgroup G1 and a second subgroup G2 adjacent to each other may be disposed to face each other in the first direction DR1. According to this embodiment, since the emission connection parts CE form a contact group CG and are disposed adjacent to each other, a region which may be utilized as a light-emitting area of the emitting part may be widened, thereby improving the design freedom of the emitting part and widely securing the light-emitting area of the emitting part.

As illustrated in FIG. 4C, the first electrode EL1 (hereinafter referred to as an anode) according to an embodiment of the inventive concept may be commonly provided to the plurality of emitting parts EP1, EP2, and EP3. That is, the anode EL1 may be provided in an integral shape and disposed to overlap the emitting parts EP1, EP2, and EP3 or the separator SPR. As described above, the first power voltage VDD (see FIG. 1) may be applied to the anode EL1 and a common voltage may be provided to all emitting parts EP1, EP2, and EP3. The anode EL1 may be connected to the first power line VDL (see FIG. 2A) configured to provide the first power voltage VDD (see FIG. 1) in the peripheral region NDA (see FIG. 3A) or may be connected to the first power line VDL (see FIG. 2A) in the display region DA, and the inventive concept is not limited to any one embodiment.

Meanwhile, a plurality of openings OP-EL1 may be formed through the anode EL1 according to this embodiment. The openings OP-EL1 may be disposed not to overlap the emitting parts EP and generally defined at positions overlapping the separator SPR. The openings OP-EL1 may facilitate the discharge of gas generated from an organic layer disposed below the anode EL1, for example, a sixth insulating layer 60 (see FIG. 5), which will be described later. Accordingly, in the process of manufacturing the display panel DP (see FIG. 1), gas from the organic layer disposed below the light-emitting device may be sufficiently discharged through the openings OP-EL1, and as the amount of gas discharged from the organic layer after manufacturing is reduced, it is possible to reduce the deterioration rate of the light-emitting device LD (see FIG. 2A or FIG. 2B).

According to this inventive concept, as a connection line is included between the light-emitting device and the pixel driver, it is possible to easily connect the light-emitting device to the pixel driver by changing only the shape of the cathode without changing the arrangement or shape of the light-emitting devices. Accordingly, the design freedom for the arrangement of the pixel driver may be improved, and the area or resolution of the emitting part of the display panel may be easily increased.

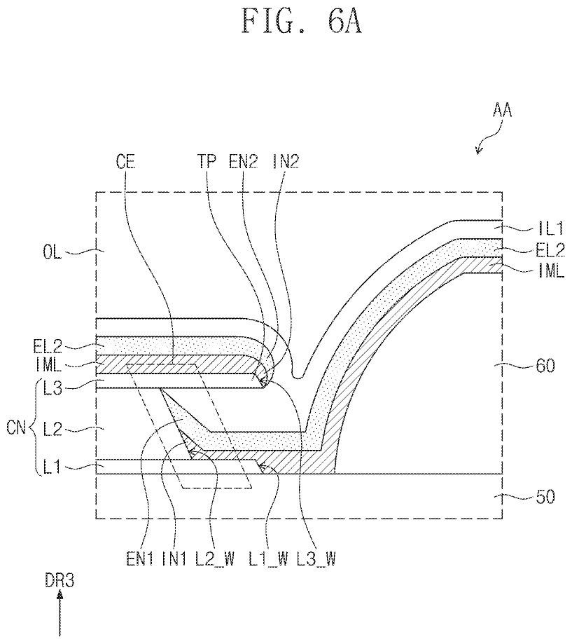

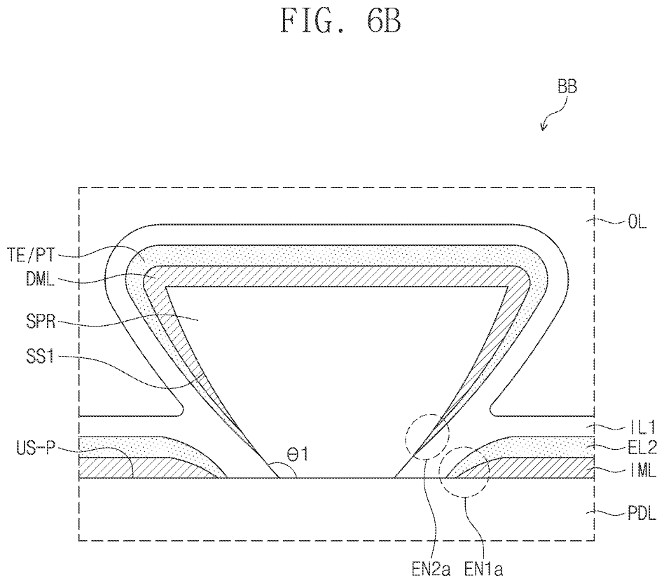

FIG. 5 is an enlarged cross-sectional view illustrating a partial region of the display panel according to an embodiment of the inventive concept, which is taken along line I-I′ of FIG. 4B. FIG. 6A is an enlarged cross-sectional view illustrating a partial region of the display panel according to an embodiment of the inventive concept, which corresponds to a region AA of FIG. 5. FIG. 6B is an enlarged cross-sectional view illustrating a partial region of the display panel according to an embodiment of the inventive concept, which corresponds to a region BB of FIG. 5.

Referring to FIG. 5, the display panel DP according to an embodiment of the inventive concept may include a base layer BS, a driving device layer DDL, a light-emitting device layer LDL, a sensing electrode TE, and an encapsulation layer ECL. The driving device layer DDL may include a plurality of insulating layers 10, 20, 30, 40, and 50 disposed on the base layer BS, and a plurality of conductive patterns and semiconductor patterns disposed between the insulating layers. The conductive patterns and semiconductor patterns may be disposed between the insulating layers to constitute the pixel driver PDC. For ease of explanation, FIG. 5 illustrates a cross section of one of the regions in which one emitting part is disposed.

The base layer BS may be a member configured to provide a base surface on which the pixel driver PDC is disposed. The base layer BS may be a rigid substrate or a flexible substrate capable of being bent, folded, or rolled. The base layer BS may be a glass substrate, a metal substrate, or a polymer substrate. However, the embodiment of the inventive concept is not limited thereto, and the base layer BS may be an inorganic layer, an organic layer, or a composite material layer.

The base layer BS may have a multi-layered structure. The base layer BS may include a first polymer resin layer, a silicon oxide (SiOx) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin layer may include a polyimide-based resin. In addition, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. Meanwhile, in this specification, a “˜˜”-based resin means to include a functional group of “˜˜”.

Each of insulating layers, conductive layers, and semiconductor layers disposed on the base layer BS may be formed by coating, deposition, or the like. Hereafter, the insulating layer, the semiconductor layer, and the conductive layer may be selectively patterned through a plurality of photolithography processes to form a hole in the insulating layer, or a semiconductor pattern, a conductive pattern, a signal line, and the like may be formed.

The driving device layer DDL may include first to fifth insulating layers 10, 20, 30, 40, and 50 sequentially stacked on the base layer BS and a pixel driver PDC. FIG. 5 illustrates one transistor TR and two capacitors C1 and C2 included in the pixel driver PDC. The transistor TR may correspond to a transistor connected to the light-emitting device LD through a connection line CN, that is, a connection transistor connected to a node (fourth node N4 of FIG. 2A, or second node N2 of FIG. 2B) corresponding to the cathode of the light-emitting device LD, and specifically, the transistor TR may correspond to the sixth transistor T6 of FIG. 2A or the first transistor T1 of FIG. 2B. Meanwhile, although not illustrated, other transistors constituting the pixel driver PDC may have the same structure as the transistor TR (hereinafter referred to as a connection transistor) illustrated in FIG. 5. However, this is described as an example, and other transistors constituting the pixel driver PDC may have structures different from that of the connection transistor TR, and the inventive concept is not limited to any one embodiment.

The first insulating layer 10 may be disposed on the base layer BS. The first insulating layer 10 may be an inorganic layer and/or an organic layer, and may have a single-layered or multi-layered structure. The first insulating layer 10 may include at least one of aluminum oxide, titanium oxide, silicon oxide, silicon nitride, silicon oxynitride, zirconium oxide, and hafnium oxide. In this embodiment, the first insulating layer 10 is illustrated as a single-layered silicon oxide layer. Meanwhile, insulating layers to be described later may be inorganic layers and/or organic layers and may have a single-layered or multi-layered structure. An inorganic layer may include at least one of the above materials, but is not limited thereto.

Meanwhile, the first insulating layer 10 may cover a bottom conductive layer BCL. That is, the display panel DP may further include the bottom conductive layer BCL disposed to overlap the connection transistor TR. The bottom conductive layer BCL may block an electric potential due to a polarization phenomenon of the base layer BS from affecting the connection transistor TR. In addition, the bottom conductive layer BCL may block light incident from the lower side to the connection transistor TR. At least one of an inorganic barrier layer or a buffer layer may be further disposed between the bottom conductive layer BCL and the base layer BS.

The bottom conductive layer BCL may contain a reflective metal. For example, the bottom conductive layer BCL may contain titanium (Ti), molybdenum (Mo), an alloy containing molybdenum, aluminum (Al), an alloy containing aluminum, aluminum nitride (AlN), tungsten (W), tungsten nitride (WN), copper (Cu), and/or the like.

In this embodiment, the bottom conductive layer BCL may be connected to a source of the connection transistor TR through a source electrode pattern W1. In this case, the bottom conductive layer BCL may have the same electric potential as the source of the connection transistor TR. However, this is illustrated as an example, and the bottom conductive layer BCL may be connected to the gate of the connection transistor TR to have the same electric potential as the gate of the connection transistor TR. Alternatively, the bottom conductive layer BCL may be connected to another electrode to independently receive a constant voltage or a pulse signal. Alternatively, the bottom conductive layer BCL may be a floating pattern which is not connected to other conductive patterns. The bottom conductive layer BCL according to an embodiment of the inventive concept may be provided in various forms and is not limited to any one embodiment.

The connection transistor TR may be disposed on the first insulating layer 10. The connection transistor TR may include a semiconductor pattern SP and a gate electrode GE. The semiconductor pattern SP may be disposed on the first insulating layer 10. The semiconductor pattern SP may include an oxide semiconductor. For example, the oxide semiconductor may include transparent conductive oxide (TCO) such as indium tin oxide (ITO), indium zinc oxide (IZO), indium gallium zinc oxide (IGZO), zinc oxide (ZnO) or indium oxide (In2O3). Without being limited thereto, however, the semiconductor pattern may include amorphous silicon, low-temperature polycrystalline silicon, or polycrystalline silicon.

The semiconductor pattern SP may include a source region SR, a drain region DR, and a channel region CR which are distinguished according to the degree of conductivity. The channel region CR may overlap the gate electrode GE in a plan view. The source region SR and the drain region DR may be spaced apart from each other with the channel region CR interposed therebetween. When the semiconductor pattern SP is an oxide semiconductor, each of the source region SR and the drain region DR may be a reduced region. Accordingly, the source region SR and the drain region DR have a reduced metal content which is relatively higher than that of the channel region CR. Alternatively, when the semiconductor pattern SP is made of polycrystalline silicon, each of the source region SR and the drain region DR may be a region highly doped with impurities to enhance conductivity.

The source region SR and the drain region DR may have relatively higher conductivity than the channel region CR. The source region SR may correspond to the source electrode of the connection transistor TR, and the drain region DR may correspond to the drain electrode of the connection transistor TR. As illustrated in FIG. 5, a separate source electrode pattern W1 and a separate drain electrode pattern W2 respectively connected to the source region SR and the drain region DR may be further provided. Specifically, each of the separate source electrode pattern W1 and the separate drain electrode pattern W2 may be integrally formed with one of the lines constituting the pixel driver (see FIGS. 2A and 2B), and the inventive concept is not limited to any one embodiment.

The second insulating layer 20 may overlap a plurality of pixels in common and cover the semiconductor pattern SP. The second insulating layer 20 may be an inorganic layer and/or an organic layer and have a single-layered or multi-layered structure. The second insulating layer 20 may include at least one of aluminum oxide, titanium oxide, silicon oxide, silicon nitride, silicon oxynitride, zirconium oxide, and hafnium oxide. In this embodiment, the second insulating layer 20 may be a single-layered silicon oxide layer.

The gate electrode GE may be disposed on the second insulating layer 20. The gate electrode GE may correspond to the gate of the connection transistor TR. In addition, the gate electrode GE may be disposed above the semiconductor pattern SP to overlap the channel region CR of the connection transistor TR. However, this is illustrated as an example, and the gate electrode GE may be disposed below the semiconductor pattern SP, and the inventive concept is not limited to any one embodiment.

The gate electrode GE may contain titanium (Ti), silver (Ag), molybdenum (Mo), aluminum (Al), aluminum nitride (AlN), tungsten (W), tungsten nitride (WN), copper (Cu), or alloys thereof, but is not particularly limited thereto.

The third insulating layer 30 may be disposed on the gate electrode GE. The third insulating layer 30 may be an inorganic layer and/or an organic layer and have a single-layered or multi-layered structure. The third insulating layer 30 may include at least one of aluminum oxide, titanium oxide, silicon oxide, silicon nitride, silicon oxynitride, zirconium oxide, and hafnium oxide.

Among a plurality of conductive patterns W1, W2, CPE1, CPE2, and CPE3, the first capacitor electrode CPE1 and the second capacitor electrode CPE2 constitute the first capacitor C1. The first capacitor electrode CPE1 and the second capacitor electrode CPE2 may be spaced apart from each other with the first insulating layer 10 and the second insulating layer 20 interposed therebetween.

In an embodiment of the inventive concept, the first capacitor electrode CPE1 and the bottom conductive layer BCL may have an integral shape. In addition, the second capacitor electrode CPE2 and the gate electrode GE may have an integral shape.

The third capacitor electrode CPE3 may be disposed on the third insulating layer 30. The third capacitor electrode CPE3 may be spaced apart from the second capacitor electrode CPE2 with the third insulating layer 30 interposed therebetween and overlap the second capacitor electrode CPE2 in a plan view. The third capacitor electrode CPE3 and the second capacitor electrode CPE2 may constitute the second capacitor C2 with the third insulating layer 30 disposed therebetween.

The fourth insulating layer 40 may be disposed on the third insulating layer 30 and/or the third capacitor electrode CPE3. The fourth insulating layer 40 may be an inorganic layer and/or an organic layer and have a single-layered or multi-layered structure. The fourth insulating layer 40 may contain at least one of aluminum oxide, titanium oxide, silicon oxide, silicon nitride, silicon oxynitride, zirconium oxide, or hafnium oxide.

The source electrode pattern W1 and the drain electrode pattern W2 may be disposed on the fourth insulating layer 40. The source electrode pattern W1 may be connected to the source region SR of the connection transistor TR through a first contact hole CNT1, and the source electrode pattern W1 and the source region SR of the semiconductor pattern SP may function as a source of the connection transistor TR. The drain electrode pattern W2 may be connected to the drain region DR of the connection transistor TR through a second contact hole CNT2, and the drain electrode pattern W2 and the drain region DR of the semiconductor pattern SP may function as a drain of the connection transistor TR. The fifth insulating layer 50 may be disposed on the source electrode pattern W1 and the drain electrode pattern W2.

The connection line CN may be disposed on the fifth insulating layer 50. The connection line CN may electrically connect the pixel driver PDC to the light-emitting device LD. That is, the connection line CN may electrically connect the connection transistor TR to the light-emitting device LD. The connection line CN may be a connection node connecting the pixel driver PDC and the light-emitting device LD. That is, the connection line CN may correspond to the fourth node N4 (see FIG. 2A) illustrated in FIG. 2A or the second node N2 (see FIG. 2B) illustrated in FIG. 2B. Meanwhile, this is described as an example, and as long as the connection line CN can be connected to the light-emitting device LD, the connection line CN may be defined as a connection node for various elements among elements constituting the pixel driver PDC according to the design of the pixel driver PDC, and the inventive concept is not limited to any one embodiment.

The sixth insulating layer 60 may be disposed on the connection line CN. The sixth insulating layer 60 may be disposed on the fifth insulating layer 50 to cover the connection line CN. Each of the fifth insulating layer 50 and the sixth insulating layer 60 may be an organic layer. For example, each of the fifth insulating layer 50 and the sixth insulating layer 60 may contain a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylic-based polymer, an imide-based polymer, an aryl ether-based polymer, an amide-based polymer, a fluorine-based polymer, a p-xylene-based polymer, a vinyl alcohol-based polymer, and/or blends thereof.

An opening exposing at least a portion of the connection line CN may be provided in the sixth insulating layer 60. The connection line CN may be electrically connected to the light-emitting device LD through the portion which is not covered by the sixth insulating layer 60, for example, the emission connection part CE. That is, the connection line CN may electrically connect the connection transistor TR to the light-emitting device LD. A detailed description thereof will be given later. Meanwhile, in the display panel DP according to an embodiment of the inventive concept, the sixth insulating layer 60 may be omitted or provided in plurality, and the inventive concept is not limited to any one embodiment.

The light-emitting device layer LDL may be disposed on the sixth insulating layer 60. The light-emitting device layer LDL may include a pixel defining layer PDL, a light-emitting device LD, and a separator SPR. The pixel defining layer PDL may be an organic layer. For example, the pixel defining layer PDL may contain a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylic-based polymer, an imide-based polymer, an aryl ether-based polymer, an amide-based polymer, a fluorine-based polymer, a p-xylene-based polymer, a vinyl alcohol-based polymer, and/or blends thereof.

In an embodiment of the inventive concept, the pixel defining layer PDL may have a property of absorbing light and have, for example, a black color. That is, the pixel defining layer PDL may contain a black coloring agent. The black coloring agent may include black dye and black pigment. The black coloring agent may include carbon black, a metal such as chromium, or an oxide thereof. The pixel defining layer PDL may correspond to a light blocking pattern having light blocking characteristics.

An opening OP-E (hereinafter referred to as a light-emitting opening) exposing at least a portion of a first electrode EL1 to be described later may be formed in the pixel defining layer PDL. A plurality of light-emitting openings OP-E may be disposed to correspond to light-emitting devices LD, respectively. In the light-emitting opening OP-E, all elements of the light-emitting device LD may be disposed to overlap each other and the light-emitting opening OP-E may be a region through which light emitted by the light-emitting device LD is substantially displayed. Accordingly, the shapes of the emitting parts EP1, EP2, and EP3 described above (see FIG. 4A) may substantially correspond to the shapes of the light-emitting openings OP-E in a plan view.

The light-emitting device LD may include a first electrode EL1, an intermediate layer IML, and a second electrode EL2. The first electrode EL1 may be a semi-transmissive, transmissive, or reflective electrode. According to an embodiment of the inventive concept, the first electrode EL1 may include: a reflective layer formed of silver (Ag), magnesium (Mg), aluminum (Al), platinum (Pt), palladium (Pd), gold (Au), nickel (Ni). neodymium (Nd), iridium (Ir), chromium (Cr), or a compound thereof; and a transparent or semi-transparent electrode layer formed on the reflective layer. The transparent or semi-transparent electrode layer may contain at least one selected from the group consisting of indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode EL1 may include a stacked structure of ITO/Ag/ITO.

In this embodiment, the first electrode EL1 may be an anode of the light-emitting device LD. That is, the first electrode EL1 may be connected to the first power line VDL (see FIG. 2A) and the first power voltage VDD (see FIG. 2A) may be applied to the light-emitting device LD through the first power line VDL. The first electrode EL1 may be connected to the first power line VDL (see FIG. 2A) in the display region DA, or may be connected to the first power line VDL (see FIG. 2A) in the peripheral region NDA (see FIG. 3A). In the latter case, the first power line VDL (see FIG. 2A) may be disposed in the peripheral region NDA (see FIG. 3A), and the first electrode EL1 may have a shape extending to the peripheral region NDA.

Although the cross-sectional view of FIG. 5 illustrates that the first electrode EL1 overlaps a light-emitting opening OP-E and does not overlap the separator SPR, as described above with reference to FIG. 4C, the first electrodes EL1 of each light-emitting device may have an integral shape and may have a mesh or lattice shape in which openings are defined in a partial region. That is, as long as a same first power voltage VDD (see FIG. 1) can be applied to the first electrode EL1 of each of the plurality of light-emitting devices, the shape of the first electrode EL1 may be altered in various ways, and the inventive concept is not limited to any one embodiment.

The intermediate layer IML may be disposed between the first electrode EL1 and the second electrode EL2. The intermediate layer IML may include a light-emitting layer EML and a functional layer FNL. The light-emitting device LD may include an intermediate layer IML having various structures and the structure of the light-emitting device LD is not limited to any one embodiment. For example, the functional layer FNL may be provided as a plurality of layers or as two or more layers spaced apart from each other with the light-emitting layer EML interposed therebetween. Alternatively, in an embodiment of the inventive concept, the functional layer FNL may be omitted.

The light-emitting layer EML may contain an organic light-emitting material. In addition, the light-emitting layer EML may contain an inorganic light-emitting material or may include a mixed layer of an organic light-emitting material and an inorganic light-emitting material. In this embodiment, the light-emitting layer EML may contain a light-emitting material, and the light-emitting layers EML respectively included in the first to third light-emitting devices LD1, LD2, and LD3 (see FIG. 4B) may contain light-emitting materials which display different colors. For example, the light-emitting layers included in the first to third light-emitting devices may emit any one of blue light, red light, and green light. Without being limited thereto, however, all of the light-emitting layers EML may contain a light-emitting material which displays a same color. In this case, the light-emitting layer EML may provide blue light or white light. In addition, FIG. 5 illustrates an embodiment in which the light-emitting layer EML and the functional layer FNL have different shapes, but without being limited thereto, the light-emitting layer EML and the functional layer FNL may be disposed in a same shape in a plan view.

The functional layer FNL may be disposed between the first electrode EL1 and the second electrode EL2. Specifically, the functional layer FNL may be disposed between the first electrode EL1 and the light-emitting layer EML or between the second electrode EL2 and the light-emitting layer EML. Alternatively, the functional layer FNL may be disposed not only between the first electrode EL1 and the light-emitting layer EML, but also between the second electrode EL2 and the light-emitting layer EML. In this embodiment, the light-emitting layer EML is illustrated as being inserted into the functional layer FNL. However, this is illustrated as an example, and the functional layer FNL may be disposed between the light-emitting layer EML and the first electrode EL1, and/or disposed between the light-emitting layer EML and the second electrode EL2. Each of the functional layer FNL may be provided in plurality, and the inventive concept is not limited to any one embodiment.

The functional layer FNL may control the movement of charge between the first electrode EL1 and the second electrode EL2. The functional layer FNL may contain a hole injection/transport material and/or an electron injection/transport material. The functional layer FNL may include at least one of an electron blocking layer, a hole transport layer, a hole injection layer, a hole blocking layer, an electron transport layer, an electron injection layer, and a charge generation layer.

The second electrode EL2 may be disposed on the intermediate layer IML. As described above, the second electrode EL2 may be connected to the connection line CN and electrically connected to the pixel driver PDC. That is, the second electrode EL2 may be electrically connected to the connection transistor TR through the connection line CN.

As described above, the connection line CN may include a driver connection part CD (or first connection part) and an emission connection part CE (or second connection part). The driver connection part CD may be a portion of the connection line CN connected to the pixel driver PDC and is connected to the connection transistor TR. In this embodiment, the driver connection part CD may be formed in a contact hole form through the fifth insulating layer 50 and be electrically connected to the drain region DR of the semiconductor pattern SP through the drain electrode pattern W2. The emission connection part CE may be a portion of the connection line CN that is connected to the light-emitting device LD. The emission connection part CE may be a region of the connection line CN not covered by the sixth insulating layer 60 and may be a portion to which the second electrode EL2 is connected. In this case, a tip part TP may be formed in the emission connection part CE.

The emission connection part CE of the connection line CN will be described in more detail with reference to FIGS. 5 and 6A. As illustrated in FIGS. 5 and 6A, the connection line CN may have a three-layered structure. Specifically, the connection line CN may include a first layer L1, a second layer L2, and a third layer L3 stacked along the third direction DR3. The second layer L2 may contain a material different from that of the first layer L1. In addition, the second layer L2 may contain a material different from that of the third layer L3. The second layer L2 may have a relatively large thickness compared to the first layer L1. In addition, the second layer L2 may have a relatively large thickness compared to the third layer L3. The second layer L2 may contain a highly conductive material. In an embodiment of the inventive concept, the second layer L2 may contain aluminum (Al).

Meanwhile, the first layer L1 may contain a material having a lower etch rate than the second layer L2 to an etchant. That is, the first layer L1 and the second layer L2 may include materials having a high etching selectivity to the etchant. In an embodiment of the inventive concept, the first layer L1 may contain titanium (Ti), and the second layer L2 may contain aluminum (Al). In this case, a side surface L1_W of the first layer L1 may protrude more outward than a side surface L2_W of the second layer L2. That is, the emission connection part CE of the connection line CN may have a shape in which the side surface L1_W of the first layer L1 protrudes outward from the side surface L2_W of the second layer L2. That is, the emission connection part CE of the connection line CN may have a shape in which the side surface L2_W of the second layer L2 is recessed inward from the side surface L1_W of the first layer L1.

In addition, the third layer L3 may contain a material having a lower etch rate than the second layer L2 to the etchant. That is, the third layer L3 and the second layer L2 may include materials having a high etching selectivity to the etchant. In an embodiment of the inventive concept, the third layer L3 may contain titanium (Ti), and the second layer L2 may contain aluminum (Al). In this case, a side surface L3_W of the third layer L3 may protrude more outward than the side surface L2_W of the second layer L2. That is, the emission connection part CE of the connection line CN may have a shape in which the side surface L3_W of the third layer L3 protrudes outward from the side surface L2_W of the second layer L2. That is, the emission connection part CE of the connection line CN may have an undercut portion in the second layer L2 or an overhang structure in the third layer L3, and a tip part TP of the connection line CN which is a protruding portion of the third layer L3 protruding more than the second layer L2 may be formed.

The sixth insulating layer 60 and the pixel defining layer PDL may expose at least a portion of the tip part TP and at least a portion of the side surface L2_W of the second layer L2. Specifically, a first contact opening OP1-C exposing one side of the connection line CN may be formed in the sixth insulating layer 60, and a second contact opening OP2-C overlapping the first contact opening OP1-C may be defined in the pixel defining layer PDL. A planar area of the second contact opening OP2-C may be greater than that of the first contact opening OP1-C. However, the inventive concept is not limited thereto, and as long as at least a portion of the tip part TP and at least a portion of the side surface L2_W of the second layer L2 can be exposed, the planar area of the second contact opening OP2-C may be smaller than or equal to that of the first contact opening OP1-C.

The intermediate layer IML may be disposed on the pixel defining layer PDL. The intermediate layer IML may also be disposed on a partial region of the sixth insulating layer 60 not covered by the pixel defining layer PDL. In addition, the intermediate layer IML may be disposed on a partial region of the connection line CN not covered by the sixth insulating layer 60. As illustrated in FIG. 6A, the intermediate layer IML may include one end IN1 disposed along the upper surface of the fifth insulating layer 50 and the other end IN2 disposed along the upper surface of the connection line CN on the tip part TP. That is, when viewed in a cross sectional view, the intermediate layer IML may have a shape in which the intermediate layer IML is partially disconnected with respect to the tip part TP in a region in which the emission connection part CE is defined. However, in a plan view, the intermediate layer IML may have an integral shape in which the intermediate layer IML is wholly connected in a region (i.e., an opening region corresponding to the separating opening OP-S) enclosed by the separator SPR.

The second electrode EL2 may be disposed on the intermediate layer IML. The second electrode EL2 may also be disposed on a partial region of the sixth insulating layer 60 not covered by the pixel defining layer PDL. In addition, the second electrode EL2 may also be disposed on a partial region of the connection line CN not covered by the sixth insulating layer 60. As illustrated in FIG. 6A, the second electrode EL2 may include one end EN1 connected to the second layer L2and the other end EN2 disposed on the tip part TP to cover the tip part TP. That is, in a cross sectional view, the second electrode EL2 may have a shape in which the second electrode EL2 is partially disconnected under the tip part TP. However, in a plan view, the second electrode EL2 may have an integral shape in which the second electrode EL2 is wholly connected in a region (i.e., an opening region corresponding to the separating opening OP-S) enclosed by the separator SPR.

Meanwhile, one end EN1 of the second electrode EL2 may be disposed along and in contact with the side surface L2_W of the second layer L2. Specifically, by a difference in deposition angle between the second electrode EL2 and the intermediate layer IML, the second electrode EL2 may be formed to be in contact with the side surface L2_W of the second layer L2 exposed by the intermediate layer IML under the tip part TP. That is, the second electrode EL2 may be connected to the connection line CN without a separate patterning process for the intermediate layer IML, and thus the light-emitting device LD may be electrically connected to the pixel driver PDC through the connection line CN.

In addition, in this embodiment, the other end IN2 of the intermediate layer IML and the other end EN2 of the second electrode EL2 are illustrated as covering the side surface L3_W of the third layer L3, but this is illustrated as an example, and at least a portion of the side surface L3_W of the third layer L3 may not be covered by the intermediate layer IML and/or the second electrode EL2.

In this embodiment, the second electrode EL2 and the intermediate layer IML may be commonly deposited and formed in a plurality of pixels by using an open mask, and in this case, the second electrode EL2 and the intermediate layer IML may be disconnected along the separator SPR. As described above, the separator SPR may have a closed-line shape for each emitting part, and thus the second electrode EL2 and the intermediate layer IML may have an isolated shape for each emitting part. In other words, a separating opening OP-S corresponding to each light-emitting opening OP-E may be formed in the separator SPR, and the second electrode EL2 and the intermediate layer IML may be disconnected and disposed in each separating opening OP-S. Specifically, the light-emitting opening OP-E may overlap a corresponding separating opening OP-S, and, in a plan view, the light-emitting opening OP-E may be disposed in a corresponding separating opening OP-S. That is, the second electrode EL2 and the intermediate layer IML may be formed as an isolated pattern for each pixel.

The separator SPR will be described in more detail with reference to FIGS. 5 and 6B. As illustrated in FIG. 6B, the separator SPR may have a reverse tapered shape. That is, an interior angle θ1 (hereinafter referred to as a first taper angle θ1) formed by a side surface SS1 of the separator SPR with respect to an upper surface US-P of the pixel defining layer PDL may be an obtuse angle. In this specification, the internal angle formed by one side surface of the separator SPR with respect to the upper surface US-P of the pixel defining layer PDL may mean an angle measured from the inside of the separator SPR. However, this is illustrated as an example, and as long as the separator SPR can electrically disconnect the second electrode EL2 for each pixel, the first taper angle θ1 may be set in various ways. In addition, the separator SPR may include a structure such as a tip part TP, and the inventive concept is not limited to any one embodiment.

In an embodiment of the inventive concept, the separator SPR may contain an insulating material, particularly an organic insulating material. The separator SPR may contain an inorganic insulating material, have a multi-layered structure of an organic insulating material and an inorganic insulating material, or contain a conductive material according to an embodiment of the inventive concept. That is, as long as the second electrode EL2 can be electrically disconnected along the separator SPR for each pixel, the type of material of the separator SPR is not particularly limited.

The sensing electrode TE may include a pattern portion PT at least partially disposed on the separator SPR. Specifically, at least a portion of a dummy layer DML may be disposed on the separator SPR, and at least a portion of the pattern portion PT may be disposed on the dummy layer DML. In an embodiment of the inventive concept, the dummy layer DML may be formed to cover not only the upper surface of the separator SPR but also a portion of the side surface SS1 of the separator SPR, and the pattern portion PT may also be formed to cover not only a portion of the dummy layer DML covering the upper surface of the separator SPR, but also a portion thereof covering the side surface SS1 of the separator SPR. The dummy layer DML may be formed through the same process as the intermediate layer IML, and the dummy layer DML and the intermediate layer IML may contain a same material. The pattern portion PT may be formed through the same process as the second electrode EL2, and the pattern portion PT and the second electrode EL2 may contain a same material. That is, the dummy layer DML and the pattern portion PT may be formed simultaneously in the process of forming the intermediate layer IML and the second electrode EL2.

The pattern portion PT may be a portion of the second electrode EL2 disposed on the separator SPR and disconnected along an edge of the separator SPR. As the separating opening OP-S corresponding to each light-emitting opening OP-E is defined in the separator SPR, the separator SPR may have a closed-line shape for each of the emitting parts EP1, EP2, and EP3 (see FIG. 4A), and accordingly, the second electrode EL2 may have an isolated shape for each of the emitting parts EP1, EP2, and EP3 (see FIG. 4A). As the separator SPR has a predetermined width, the pattern portion PT may be disposed on the separator SPR not to connected to the second electrode EL2. That is, the pattern portion PT and the second electrode EL2 may be electrically disconnected along the edge of the separator SPR, and the sensing electrode TE may perform a sensing function.

In this embodiment, a mesh opening OP-M may be formed in the pattern portion PT, and the mesh opening OP-M may be formed in regions correspond to the separating openings OP-S. Accordingly, the light-emitting opening OP-E overlapping the separating opening OP-S may also overlap the mesh opening OP-M formed in regions corresponding to the separating openings OP-S, and may be disposed in the mesh opening OP-M in a plan view. A detailed description of the mesh opening OP-M will be given later.

As illustrated in FIG. 6B, in an embodiment of the inventive concept, the second electrode EL2 may include a first end EN1a, and the pattern portion PT may include a second end EN2a. The first end EN1a may be spaced apart from the separator SPR and disposed on the pixel defining layer PDL, and the second end EN2a may be separated from the first end EN1a and disposed on the side surface SS1 of the separator SPR. However, in FIG. 6B, the first end EN1a is illustrated as being spaced apart from the side surface SS1 of the separator SPR by a predetermined distance, but the inventive concept is not limited thereto, and as long as the first end EN1a can be electrically disconnected from the second end EN2a, the first end EN1a may also be in contact with the side surface SS1 of the separator SPR. In addition, although the first end EN1a and the second end EN2a are connected to each other, when electrical resistance is high enough so that a reasonable amount of current is not flow from the second electrode EL2 to the pattern portion PT or vice versa, the second electrode EL2 and the pattern portion PT may be considered to be electrically disconnected from each other. In addition, when the second electrodes EL2 of pixels adjacent to each other are electrically disconnected from each other, the second electrodes EL2 may be considered to be disconnected for each pixel by the separator SPR.

According to this inventive concept, although there is no separate patterning process for the second electrode EL2 or the intermediate layer IML, the second electrode EL2 or the intermediate layer IML may be disconnected for each pixel by making the second electrode EL2 or the intermediate layer IML formed thinly or not formed on the side surface SS1 of the separator SPR. In addition, only by a deposition process of the second electrode EL2 without a separate patterning process of the sensing electrode TE, the second electrode EL2 and the sensing electrode TE which are electrically disconnected from each other may be simultaneously formed. Accordingly, in the display panel DP according to this inventive concept, a separate layer configured to sense an external input may not be formed on the encapsulation layer ECL. Accordingly, the display panel DP having a simplified process and a reduced thickness may be provided. The display panel DP having a reduced thickness may be appropriately applied not only to a rigid display panel but also to a bendable flexible display panel or a rollable display panel.

Meanwhile, as long as the second electrode EL2 or the intermediate layer IML can be electrically disconnected between adjacent pixels, the shape of the separator SPR may be modified in various ways, and the inventive concept is not limited to any one embodiment.

Referring back to FIG. 5, an encapsulation layer ECL may be disposed on the light-emitting device layer LDL and the sensing electrode TE. The encapsulation layer ECL may cover the light-emitting device LD and may also cover the separator SPR and the sensing electrode TE. The encapsulation layer ECL may include a first inorganic layer IL1, an organic layer OL, and a second inorganic layer IL2 sequentially stacked. Without being limited thereto, however, the encapsulation layer ECL may further include a plurality of inorganic layers and organic layers. In addition, the encapsulation layer ECL may be a glass substrate.

The first and second inorganic layers IL1 and IL2 may protect the light-emitting device LD from moisture and oxygen from outside the display panel DP, and the organic layer OL may protect the light-emitting device LD from foreign substances such as particles remaining in the process of forming the first inorganic layer IL1. The first and second inorganic layers IL1 and IL2 may contain a silicon nitride layer, a silicon oxynitride layer, a silicon oxide layer, a titanium oxide layer, an aluminum oxide layer, or the like. The organic layer OL may include an acryl-based organic layer, and the embodiment of the inventive concept is not limited to any one material.

In this embodiment, a light control layer RSL may be disposed on the encapsulation layer ECL. The light control layer RSL may be an anti-reflection layer that reduces reflectance of external light incident from the outside. The light control layer RSL may be a layer that selectively transmits light emitted from the light-emitting device layer LDL or blocks the reflection of external light.

In an embodiment of the inventive concept, the light control layer RSL may include a retarder and/or a polarizer. The retarder may be a film type or a liquid crystal coating type and may include a λ/2 retarder and/or a λ/4 retarder. The polarizer may also be a film type or a liquid crystal coating type. The film type may include a stretchable synthetic resin film, and the liquid crystal coating type may include liquid crystals arranged in a predetermined arrangement. The retarder and the polarizer may be implemented as one polarizing film.

In an embodiment of the inventive concept, the light control layer RSL may include color filters. The color filters may transmit light of a specific wavelength range and block light outside the corresponding wavelength range. For example, the color filters may include a color filter that transmits first color light and blocks second and third color lights, a color filter that transmits second color light and blocks first and third color lights, and a color filter that transmits third color light and blocks first and second color lights. The first to third color lights may respectively correspond to the beams of light emitted by the first to third light-emitting devices LD1, LD2, and LD3 (see FIG. 4B).

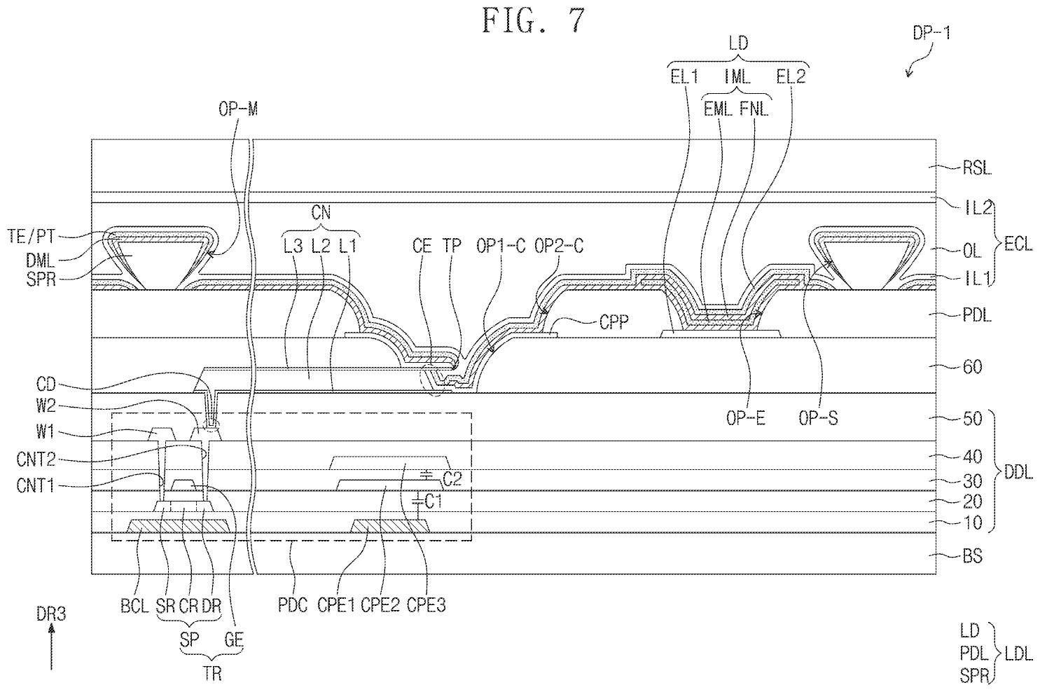

FIG. 7 is an enlarged cross-sectional view illustrating a partial region of a display panel according to an embodiment of the inventive concept. For ease of description, FIG. 7 illustrates a cross-sectional view of a region corresponding to FIG. 5. Hereinafter, same/similar reference numerals will be used for the same/similar elements as those described in FIGS. 1 to 6B, and redundant descriptions will be omitted.

A display panel DP-1 illustrated in FIG. 7 may further include a capping pattern CPP compared to the display panel DP illustrated in FIG. 5. The capping pattern CPP may be disposed on the sixth insulating layer 60. In addition, the capping pattern CPP may also be disposed on a portion of the connection line CN not covered by the sixth insulating layer 60. The capping pattern CPP may be disposed to overlap the connection line CN, and specifically, may be disposed to overlap the emission connection part CE and/or the tip part TP.

In addition, as illustrated in FIG. 7, when viewed in a cross sectional view, the capping pattern CPP may have a shape in which the capping pattern CPP is partially disconnected under the tip part TP in a region in which the emission connection part CE is formed. However, in a plan view, the capping pattern CPP may have an integral shape in which the capping pattern CPP is wholly connected in the separating openings OP-S enclosed by the separator SPR. Meanwhile, one end of the partially disconnected capping pattern CPP may be in contact with a side surface of the second layer L2 of the connection line CN, and the other one end of the capping pattern CPP may be disposed on the third layer L3 of the connection line CN to cover the tip part TP.

The capping pattern CPP may contain a conductive material. Accordingly, the second electrode EL2 may be electrically connected to the connection line CN through the capping pattern CPP. That is, as the capping pattern CPP may be in contact with the side surface of the second layer L2 of the connection line CN and then the second electrode EL2 may be in contact with the capping pattern CPP, all of them may be electrically connected to each other. As the capping pattern CPP may be disposed relatively more outward than the second layer L2 of the connection line CN and the second electrode EL2 may be electrically connected to the second layer L2 just by being in contact with the capping pattern CPP instead of the side surface of the second layer L2, a connection may be made more easily between the connection line CN and the second electrode EL2.

In addition, the capping pattern CPP may contain a material having a relatively low reactivity compared to the second layer L2 of the connection line CN. For example, the capping pattern CPP may contain copper (Cu), silver (Ag), a transparent conductive oxide, or the like. As the side surface of the second layer L2 of the connection line CN is protected by the capping pattern CPP having a relatively low reactivity, oxidation of a material included in the second layer L2 may be prevented. In addition, it is possible to prevent a phenomenon in which a silver (Ag) included in the layer of the first electrode EL1 is reduced during an etching process for patterning the first electrode EL1 and then remains as particles which cause a defect.

In an embodiment of the inventive concept, the capping pattern CPP may be formed through the same process as the first electrode EL1 and contain the same material as the first electrode EL1. However, this is described as an example, and the capping pattern CPP may be formed through a process different from that of the first electrode EL1 and contain a material different from that of the first electrode EL1, and the inventive concept is not limited to any one embodiment.

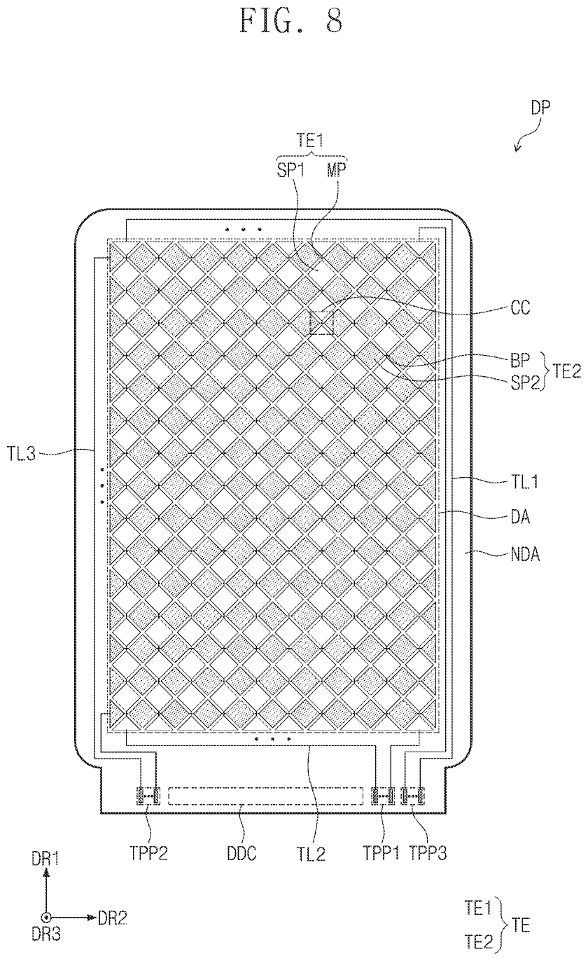

FIG. 8 is a plan view illustrating some elements of the display panel according to an embodiment of the inventive concept. FIG. 8 briefly illustrates elements for the function of sensing an external input.

Referring to FIG. 8, the display panel DP according to this embodiment may include a display region DA and a peripheral region NDA. In this embodiment, the display region DA may generate an image and sense an external input as well.

The display panel DP may include sensing electrodes TE, trace lines TL1, TL2, and TL3, and sensing pad portions TPP1, TPP2, and TPP3. The sensing electrodes TE may include a first sensing electrode TE1 and a second sensing electrode TE2.

The first sensing electrode TE1 may extend along the first direction DR1. A plurality of first sensing electrodes TE1 may be arranged along the second direction DR2. Each of the first sensing electrodes TE1 may include a plurality of first sensing patterns SP1 arranged along the first direction DR1 and intermediate patterns MP disposed between the first sensing patterns SP1.

The second sensing electrode TE2 may be electrically insulated from the first sensing electrode TE1 and driven independently of the first sensing electrode TE1. The second sensing electrode TE2 may extend along the second direction DR2. A plurality of second sensing electrodes TE2 may be arranged along the first direction DR1. The second sensing electrodes TE2 may be disposed to be insulated from and cross the first sensing electrodes TE1. Each of the second sensing electrodes TE2 may include a plurality of second sensing patterns SP2 arranged along the second direction DR2 and bridge patterns BP disposed between the second sensing patterns SP2.

When the display panel DP senses an external input, the display panel DP may be driven in a mutual capacitance method in which the first sensing electrodes TE1 and the second sensing electrodes TE2 receive different electrical signals, or in a self-capacitance method in which the first sensing electrodes TE1 and the second sensing electrodes TE2 receive a same electrical signal. Alternatively, when the display panel DP senses an external input, the display panel DP may be driven in a resistive manner in which an external input is sensed through a change in the resistance of each of the first sensing electrodes TE1 and the second sensing electrodes TE2. The display panel DP may be driven in various ways as long as it can sense an external input through the first sensing electrodes TE1 and the second sensing electrodes TE2, and the inventive concept is not limited to any one embodiment.

The trace lines TL1, TL2, and TL3 may include: first trace lines TL1 and TL2 connected to a corresponding first sensing electrode among the first sensing electrodes TE1; and second trace lines TL3 connected to a corresponding second sensing electrode among the second sensing electrodes TE2.

The first trace lines TL1 and TL2 may include 1-1st trace lines TL1 and 1-2nd trace lines TL2. The 1-1st trace lines TL1 may be connected to a corresponding end of the first sensing electrodes TE1 disposed on the top of the first sensing electrodes TE1, and the 1-2nd trace lines TL2 may be connected to a corresponding other end of the first sensing electrodes TE1 disposed on the bottom of the first sensing electrodes TE1. The second trace lines TL3 may be connected to a corresponding end of the second sensing electrodes TE2. The trace lines TL1, TL2, and TL3 may be respectively connected to corresponding sensing pad portions among sensing pad portions TPP1, TPP2, and TPP3.

A connection relationship between the trace lines TL1, TL2, and TL3 and the sensing electrodes TE1 and TE2 is not limited thereto. The trace lines TL1, TL2, and TL3 and the sensing electrodes TE1 and TE2 may be connected in various shapes, and the inventive concept is not limited to any one embodiment.

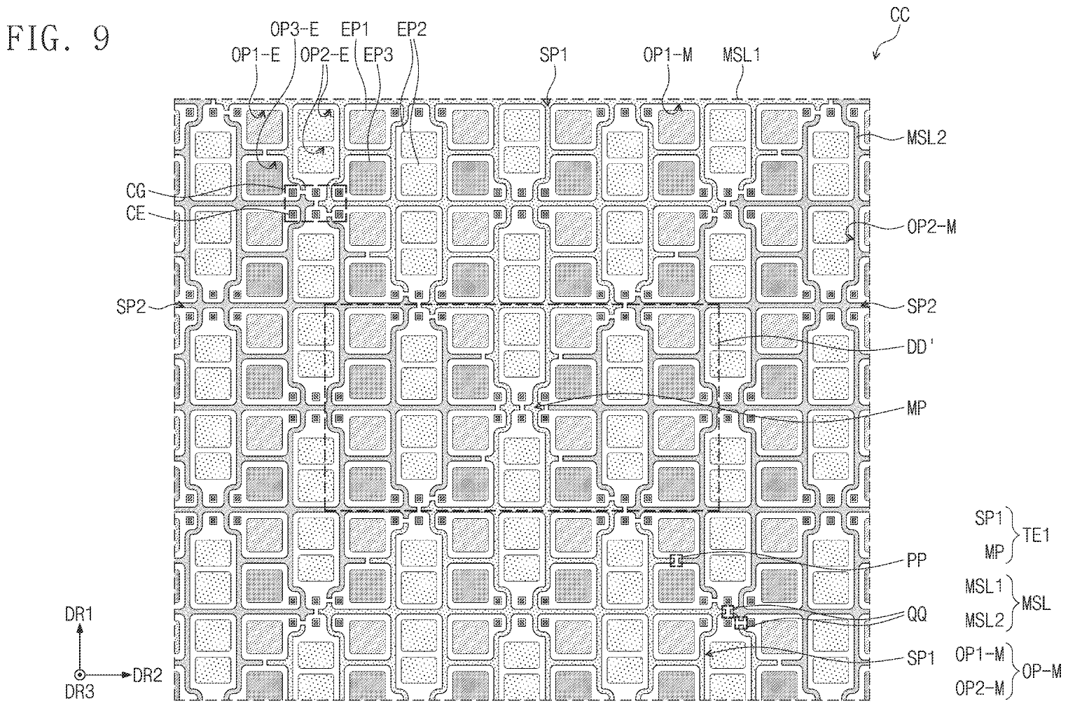

FIG. 9 is an enlarged plan view of a partial region of the display panel according to an embodiment of the inventive concept, which corresponds to a region CC of FIG. 8. FIG. 9 illustrates the first sensing patterns SP1 and the intermediate pattern MP included in one first sensing electrode TE1 among the sensing electrodes TE (see FIG. 8) and the second sensing patterns SP2 included in one second sensing electrode TE2 (see FIG. 8) among the sensing electrodes TE (see FIG. 8). For the convenience of description, FIG. 9 illustrates the emitting parts EP1, EP2, and EP3 together with the emission connection parts CE.

Referring to FIG. 9, the intermediate pattern MP may be disposed between two adjacent first sensing patterns SP1 and extend from one first sensing pattern to another first sensing pattern to connect the one first sensing pattern to the another first sensing pattern. That is, in this embodiment, the intermediate pattern MP may have an integral shape with the first sensing patterns SP1.

In this embodiment, each of the first sensing electrode TE1 and the second sensing electrode TE2 may include mesh lines MSL. According to an embodiment of the inventive concept, the mesh lines MSL may include a first mesh line MSL1 and a second mesh line MSL2. The first sensing patterns SP1 and the intermediate pattern MP in one first sensing electrode TE1 may form an integral shape, and the first sensing patterns SP1 and the intermediate pattern MP, which are integrally formed with each other, may include the first mesh line MSL1. Each of the second sensing patterns SP2 of the second sensing electrode TE2 may include the second mesh line MSL2.

In this embodiment, a mesh opening OP-M may be disposed in a region enclosed by the mesh lines MSL. According to an embodiment of the inventive concept, the mesh opening OP-M may include a plurality of first mesh openings OP1-M enclosed by the first mesh line MSL1 and a plurality of second mesh openings OP2-M enclosed by the second mesh line MSL2. The mesh opening OP-M described above in FIG. 5 may correspond to any one of the first and second mesh openings OP1-M and OP2-M.

Each of the mesh openings OP1-M and OP2-M may be disposed correspond to one of the separating openings OP-S (see FIG. 4A), and accordingly, one of the emitting parts EP1, EP2, and EP3 (or one of the light-emitting openings OP1-E, OP2-E and OP3-E) may be disposed in each of the mesh openings OP-M in a plan view.

The first mesh line MSL1 and the second mesh line MSL2 may have a shape surrounding each of the emitting parts EP1, EP2, and EP3 (or light-emitting openings OP1-E, OP2-E, and OP3-E) in a plan view. Since each of the first sensing electrode TE1 and the second sensing electrode TE2 according to an embodiment of the inventive concept is designed not to cover the emitting parts EP1, EP2, and EP3, it is possible to prevent the display characteristics of the display panel DP (see FIG. 5) from being deteriorated.

The first mesh line MSL1 and the second mesh line MSL2 may be disposed to be spaced apart from each other. In this embodiment, the first mesh line MSL1 and the second mesh line MSL2 adjacent to each other may include portions facing each other in the extension direction.

For example, the first mesh line MSL1 and the second mesh line MSL2 may include portions PP facing and spaced apart from each other between adjacent emitting parts (e.g., first emitting part EP1 and third emitting part EP3 adjacent to each other). In other words, the first mesh line MSL1 and the second mesh line MSL2 may include portions PP facing and spaced apart from each other between adjacent light-emitting openings (e.g., first light-emitting opening OP1-E and third light-emitting opening OP3-E adjacent to each other).

In addition, the first mesh line MSL1 and the second mesh line MSL2 may include portions QQ facing and spaced apart from each other between adjacent emission connection parts CE.

As described above with reference to FIGS. 4A and 4B, six emission connection parts CE may form a contact group CG and be adjacently disposed in a predetermined arrangement. As voltages having different values and varying in real time are respectively provided to the second electrodes EL2 (see FIG. 5) in the six adjacent emission connection parts CE of the contact group CG, a relatively large change in electric field may occur. According to this embodiment, as the first mesh line MSL1 and the second mesh line MSL2 adjacent to each other include boundary portions between the adjacent emitting parts EP1, EP2, and EP3, the outer edge portion of each of the first sensing pattern SP1 and the second sensing pattern SP2 is disposed in the contact group CG so that an effect on a change in sensing sensitivity can be minimized. Therefore, according to this embodiment, since sensing electrodes TE (see FIG. 8) with reduced noise with respect to the second electrode EL2 (see FIG. 5) may be provided, it is possible to provide not only the light-emitting devices LD (see FIG. 5) with reduced afterimage defects and improved lifetime, but also the display device DD (see FIG. 1) with improved sensing sensitivity.

FIG. 9 illustratively shows that one mesh opening overlaps one light emitting part. However, this is illustrated as an example, and the inventive concept is not limited to any one embodiment the mesh lines MSL may be designed so that one mesh opening OP-M overlaps a plurality of separating openings OP-S (see FIG. 4A), and accordingly, a plurality of emitting parts EP1, EP2, and EP3 (or a plurality of light-emitting openings OP1-E, OP2-E, and OP3-E) may be disposed in one mesh opening OP-M in a plan view. That is, one mesh opening OP-M may be designed to have a shape surrounding the plurality of emitting parts EP1, EP2, and EP3 (or the plurality of light-emitting openings OP1-E, OP2-E, and OP3-E).

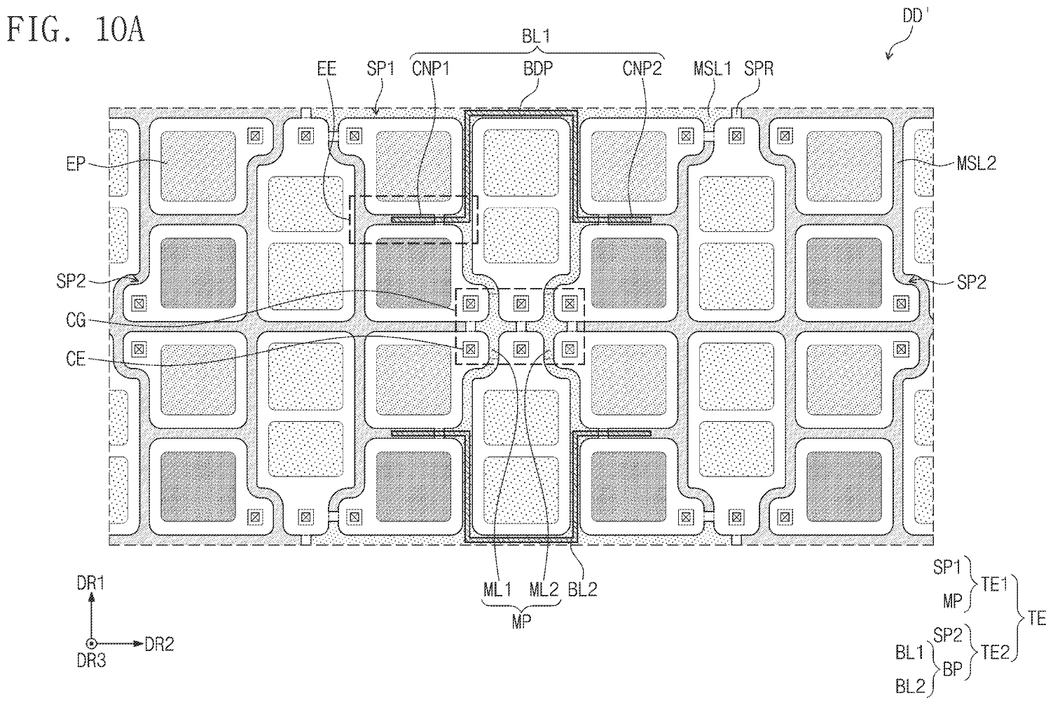

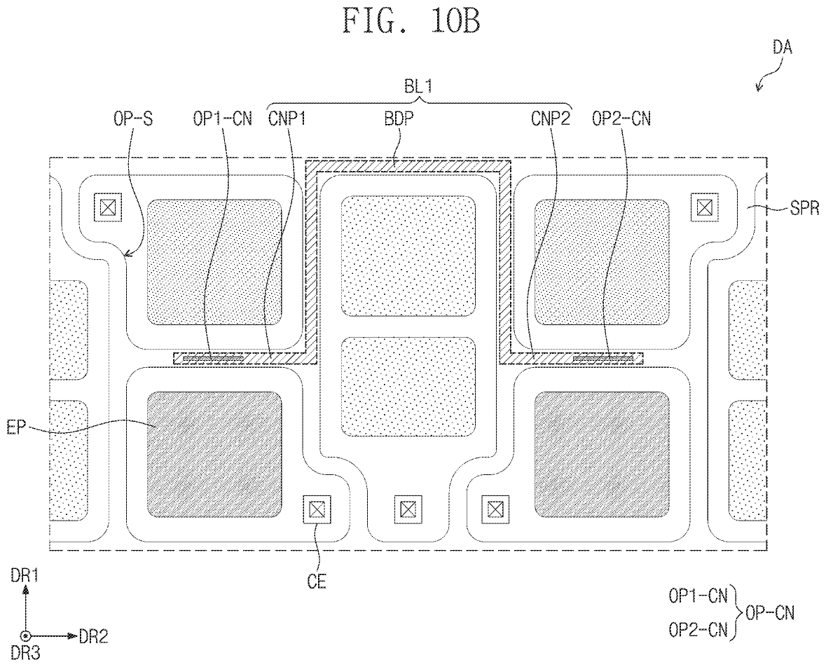

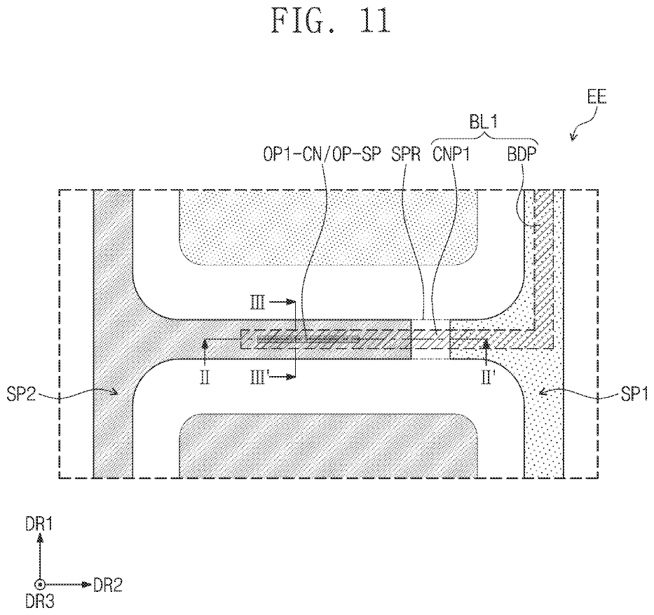

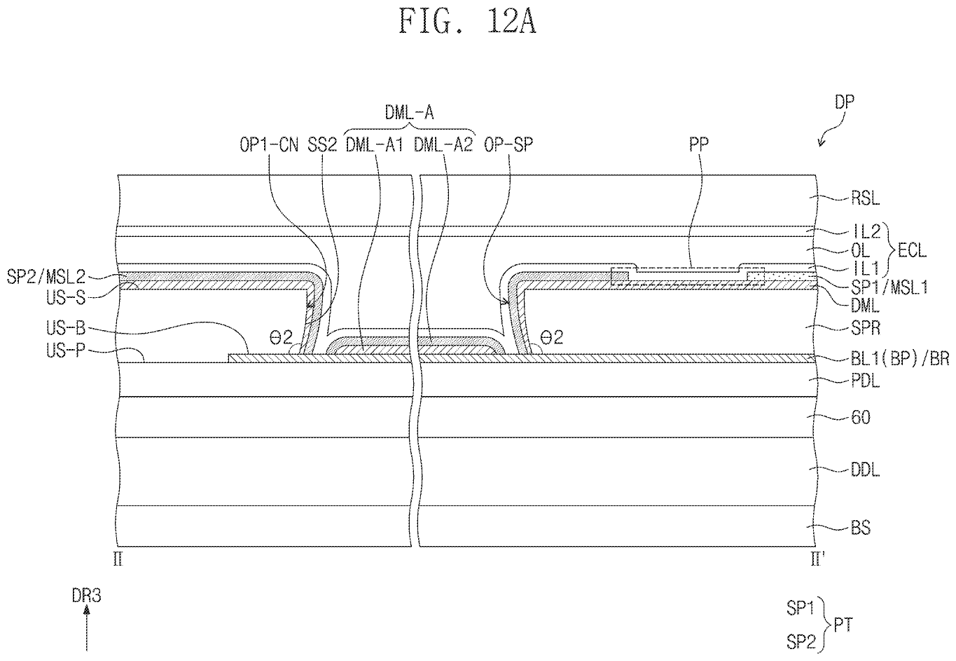

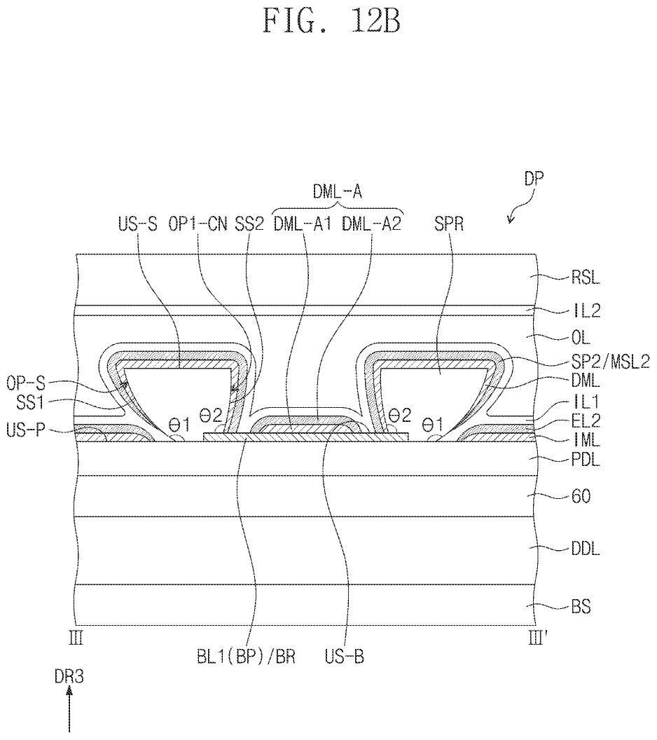

FIG. 10A is an enlarged plan view illustrating a partial region of the display panel according to an embodiment of the inventive concept which corresponds to a region DD of FIG. 9. FIG. 10B is an enlarged plan view illustrating some elements of the display panel in a display region according to an embodiment of the inventive concept. FIG. 11 is an enlarged plan view illustrating a partial region of the display panel according to an embodiment of the inventive concept, which corresponds to a region EE of FIG. 10A. FIG. 12A is an enlarged cross-sectional view illustrating a partial region of the display panel according to an embodiment of the inventive concept, which is taken along line II-II′ of FIG. 11. FIG. 12B is an enlarged cross-sectional view illustrating a partial region of the display panel according to an embodiment of the inventive concept, which is taken along line III-III′ of FIG. 11.

FIG. 10A is an enlarged view of a portion in which the first sensing electrode TE1 and the second sensing electrode TE2 are insulated from and cross each other. For the convenience of explanation, FIG. 10A illustrates the emitting parts EP, the emission connection parts CE, and the separator SPR together, and a portion of the separator SPR non-overlapping the sensing electrodes TE is illustrated in a dotted line.

Referring to FIG. 10A, the first sensing patterns SP1 of the first sensing electrode TE1 may be electrically connected to each other through an intermediate pattern MP disposed between adjacent first sensing patterns SP1, and the second sensing patterns SP2 of the second sensing electrode TE2 may be electrically connected to each other through a bridge pattern BP disposed between adjacent second sensing patterns SP2.

The intermediate pattern MP may be disposed on the same layer as the first and second sensing patterns SP1 and SP2. The bridge pattern BP may be disposed on a layer different from those of the first sensing patterns SP1, the intermediate pattern MP, and the second sensing patterns SP2. In this specification, the sensing electrodes TE may include a pattern portion PT (see FIG. 12A) and a bridge portion BR (see FIG. 12A) according to a layer on which they are disposed, and the first sensing patterns SP1, the intermediate pattern MP, and the second sensing patterns SP2 may be included in the pattern portion PT (see FIG. 12A), and the bridge pattern BP may be included in the bridge portion BR (see FIG. 12A). Referring to FIGS. 10A and 12A together, in this embodiment, the pattern portion PT may be defined as an element disposed on the separator SPR, and the bridge portion BR may be defined as an element disposed between the pixel defining layer PDL and the separator SPR. A detailed description of the arrangement relationship of the elements constituting the pattern portion PT and the bridge portion BR in a cross sectional view will be given later. Hereinafter, a detailed description of the arrangement and shape of the intermediate pattern MP and the bridge pattern BP in a plan view will be given with reference to FIG. 10A.

In this embodiment, the intermediate pattern MP may be disposed adjacent to the contact group CG. The intermediate pattern MP may be disposed to cross between adjacent emission connection parts CE.

The intermediate pattern MP may include a first intermediate line ML1 and a second intermediate line ML2. That is, the first mesh line MSL1 constituting the intermediate pattern MP may be defined as the first intermediate line ML1 and the second intermediate line ML2. Each of the first intermediate line ML1 and the second intermediate line ML2 may extend in the first direction DR1 and may be spaced apart from each other in the second direction DR2. Each of the first intermediate line ML1 and the second intermediate line ML2 may cross adjacent emission connection parts CE arranged in the second direction DR2 among the emission connection parts CE, and the first intermediate line ML1 and the second intermediate line ML2 may be spaced apart from each other in the second direction DR2 with emission connection parts CE, which are arranged in the first direction DR1 among the emission connection parts CE, interposed therebetween.

As the intermediate pattern MP is disposed to cross between the adjacent emission connection parts CE, the first sensing electrode TE1 may extend along a region protruding from the 2-1st emitting part EP2a (see FIG. 4B) in the first direction DR1 and a region protruding from the 2-2nd emitting part EP2b (see FIG. 4B) in a direction opposite to the first direction DR1. Accordingly, in a region in which the first sensing electrode TE1 and the second sensing electrode TE2 cross each other, an area occupied by the first sensing electrode TE1 may be reduced, thereby making it possible to further widen an area in which the second sensing pattern SP2 located on the same layer as the intermediate pattern MP can be disposed.

In this embodiment, the bridge pattern BP may be spaced apart from the contact group CG. In other words, the bridge pattern BP may not cross the emission connection parts CE in the contact group CG.

In this embodiment, the bridge pattern BP may include a first bridge line BL1 and a second bridge line BL2. Adjacent second sensing patterns SP2 may be electrically connected through a bridge pattern BP including two bridge lines BL1 and BL2. The first bridge line BL1 and the second bridge line BL2 may be spaced apart from each other in the first direction DR1. Each of the first bridge line BL1 and the second bridge line BL2 may include a first connection part CNP1, a second connection part CNP2, and a bent portion BDP.

The first connection part CNP1 may extend in the second direction DR2 and be disposed between the emitting parts EP arranged to be spaced apart from each other in the first direction DR1. For example, the first connection part CNP1 may be disposed between the first emitting part EP1a (see FIG. 4B) and the third emitting part EP3a (see FIG. 4B) in one light-emitting unit (e.g., UT11 of FIG. 4A).

A portion of the first connection part CNP1 may overlap the first sensing pattern SP1, and another portion of the first connection part CNP1 may overlap the second sensing pattern SP2. The first connection part CNP1 may be connected to the second sensing pattern SP2 at a portion overlapping the second sensing pattern SP2. A detailed description of the form of connection between the first connection part CNP1 and the second sensing pattern SP2 will be given later.

The second connection part CNP2 may extend in the second direction DR2 and be disposed between the emitting parts EP arranged to be spaced apart from each other in the first direction DR1. For example, the second connection part CNP2 may be disposed between the first emitting part EP1b (see FIG. 4B) and the third emitting part EP3b (see FIG. 4B) in a light-emitting unit (e.g., UT12 of FIG. 4A) adjacent to the one light-emitting unit (e.g., UT11 of FIG. 4A) in the second direction DR2.

A portion of the second connection part CNP2 may overlap the first sensing pattern SP1, and another portion of the second connection part CNP2 may overlap the second sensing pattern SP2. The second connection part CNP2 may be connected to the second sensing pattern SP2 at a portion overlapping the second sensing pattern SP2.

The bent portion BDP may be disposed between the first connection part CNP1 and the second connection part CNP2. The bent portion BDP may extend from the first connection part CNP1 to the second connection part CNP2. The bent portion BDP may extend while partially surrounding at least one emitting part EP, and thus, at least one emitting part EP may be disposed between the first connection part CNP1 and the second connection part CNP2. For example, the second emitting part EP2a (see FIG. 4B) in the one light-emitting unit may be disposed between the first connection part CNP1 and the second connection part CNP2.

The bent portion BDP of the first bridge line BL1 may extend so as to protrude in a direction away from the contact group CG (i.e., in the first direction DR1) from each of the first connection part CNP1 and the second connection part CNP2. The bent portion of the second bridge line BL2 may protrude and extend in a direction away from the contact group CG (i.e., in a direction opposite to the first direction DR1) from each of the first connection part CNP1 and the second connection part CNP2. Accordingly, the first bridge line BL1 and the second bridge line BL2 may be spaced apart from each other in the first direction DR1 with the contact group CG interposed therebetween.

According to this embodiment, as each of the first bridge line BL1 and the second bridge line BL2 has a bent portion BDP, they may be disposed to be spaced apart from the contact group CG. Accordingly, it is possible not only to reduce the effect of a change in electric field occurring in a region adjacent to the contact group CG on each of the first bridge line BL1 and the second bridge line BL2, but also to reduce or eliminate a touch noise caused by a large change in electric field occurring in other regions.

The bent portion BDP may overlap the first sensing patterns SP1. Although the bent portion BDP is disposed to overlap the first sensing patterns SP1, they may be insulated from each other since the bridge pattern BP is disposed on a layer different from that of the first sensing patterns SP1.

Meanwhile, FIG. 10A illustrates the shapes of the first and second bridge lines BL1 and BL2 as an example, and the embodiment of the inventive concept is not limited thereto. As long as the first and second bridge lines BL1 and BL2 are disposed to be spaced apart from the contact group CG and can be connected to the adjacent second sensing patterns SP2, they may have various shapes and extend along the extension direction of the separator SPR. For example, the bent portion BDP of each of the first and second bridge lines BL1 and BL2 may extend while enclosing two or more emitting parts EP.

FIG. 10B is an enlarged view of a portion of the bridge pattern BP (see FIG. 10A) in which one first bridge line BL1 is disposed. For the convenience of description, FIG. 10B illustrates the first bridge line BL1, together with the separator SPR, the emitting parts EP, and the emission connection parts CE.

In this embodiment, the first bridge line BL1 may be disposed below the separator SPR, and accordingly, the first bridge line BL1 is illustrated in a dotted line in FIG. 10B. The first bridge line BL1 may extend along a portion of the closed-line shape of the separator SPR to be completely overlapped with the separator SPR.

A connection opening OP-CN may be defined in the separator SPR. In this embodiment, the connection opening OP-CN may include a first connection opening OP1-CN and a second connection opening OP2-CN. The first connection opening OP1-CN may overlap the first connection part CNP1 of the first bridge line BL1 and expose a portion of the first connection part CNP1 from the separator SPR. The second connection opening OP2-CN may overlap the second connection part CNP2 of the first bridge line BL1 and expose a portion of the second connection part CNP2 from the separator SPR.

Meanwhile, the bent portion BDP of the first bridge line BL1 may be spaced apart from the separating openings OP-S and the connection openings OP-CN defined in the separator SPR. Accordingly, as all of the bent portion BDP is disposed to overlap the separator SPR, the bent portion BDP is entirely covered by the separator SPR and may not be exposed from the separator SPR.

In this inventive concept, a plurality of openings are defined in the separator SPR, and some of the openings of the separator SPR may correspond to the separating openings OP-S electrically disconnecting the cathode for each pixel, and other openings of the separator SPR may correspond to the connection openings OP-CN through which the pattern portion PT (see FIG. 12A) is connected to the bridge portion BR (see FIG. 12A).

FIG. 11 is an enlarged view of the region EE of FIG. 10A. FIG. 11 illustrates the first connection part CNP1 of the first bridge line BL1 and a region adjacent thereto.

Referring to FIG. 11, an opening region OP-SP may be included in a portion of the second sensing pattern SP2 overlapping the first connection part CNP1. The opening region OP-SP may be a region corresponding to the first connection opening OP1-CN of the separator SPR. The second sensing pattern SP2 may be connected to a portion of the first connection part CNP1 exposed from the separator SPR through the first connection opening OP1-CN. The opening region OP-SP may be formed to connect the second sensing pattern SP2 to the first bridge line BL1 through the first connection opening OP1-CN. Hereinafter, a connection structure between the second sensing pattern SP2 and the first bridge line BL1 will be described in detail.

Referring to FIGS. 11, 12A, and 12B together, the first mesh line MSL1 constituting the first sensing pattern SP1 and the second mesh line MSL2 constituting the second sensing pattern SP2 may be disposed on the separator SPR. The first mesh line MSL1 and the second mesh line MSL2 may be disposed on a same layer. In an embodiment of the inventive concept, a dummy layer DML may be further disposed between the separator SPR and the first and second mesh lines MSL1 and MSL2.

The first mesh line MSL1 and the second mesh line MSL2 may include portions PP facing and spaced apart from each other. In an embodiment of the inventive concept, by performing a deposition process and then a patterning process of an integrally formed layer on the separator SPR, the first mesh line MSL1 and the second mesh line MSL2 spaced apart from each other on the separator SPR may be formed. Alternatively, by using a fine metal mask (FMM) to form a patterned deposition layer during a deposition process, the first mesh line MSL1 and the second mesh line MSL2 spaced apart from each other on the separator SPR may be formed without the patterning process. Alternatively, by forming a material having a low adhesive strength to the deposition material to a portion at which the first mesh line MSL1 and the second mesh line MSL2 are spaced apart from each other prior to a deposition process, the first mesh line MSL1 and the second mesh line MSL2 spaced apart from each other on the separator SPR may be formed during the deposition process.

The separator SPR may include a first side surface SS1 defining the separating opening OP-S and a second side surface SS2 defining the first connection opening OP1-CN. The first side surface SS1 may correspond to the side surface SS1 of the separator SPR described above with reference to FIG. 6B. As illustrated in FIG. 12B, the first and second side surfaces SS1 and SS2 may include portions opposite to each other.

In this embodiment, an interior angle θ2 (hereinafter referred to as a second taper angle θ2) formed between the second side surface SS2 and the upper surface US-P of the pixel defining layer PDL may be smaller than the interior angle θ1 (i.e., first taper angle) formed between the first side surface SS1 and the upper surface US-P of the pixel defining layer PDL. In an embodiment of the inventive concept, the first taper angle θ1 may be greater than about 95 degrees, and the second taper angle θ2 may be from about 90 degrees to about 95 degrees.

As described above with reference to FIG. 6B, as the first side surface SS1 of the separator SPR has the first taper angle θ1 sufficient to disconnect a deposition layer formed on the separator SPR, the second electrode EL2 of the light-emitting device LD (see FIG. 5) and the pattern portion PT of the sensing electrode TE (see FIG. 6B) may be electrically disconnected along an edge of the first side surface SS1.

On the other hand, as the second side surface SS2 of the separator SPR has the relatively small second taper angle θ2, the deposition layer is deposited while covering the entire second side surface SS2 and may come in contact with the first bridge line BL1 of the bridge pattern BP. In this embodiment, the second sensing pattern SP2 may extend along the second side surface SS2 from the upper surface US-S of the separator SPR and come into contact with an upper surface US-B of the first bridge line BL1 of the bridge pattern BP.

That is, according to this embodiment, the pattern portion PT of the sensing electrode TE (see FIG. 6B) disposed on the separator SPR and the bridge pattern BP of the bridge portion BR of the sensing electrode TE (see FIG. 6B) disposed between the pixel defining layer PDL and the separator SPR may come in contact with each other through the connection openings OP1-CN of the separator SPR exposing a portion of the bridge pattern BP. In this case, by controlling the second taper angle θ2 of the second side surface SS2 of the separator SPR defining the connection opening OP1-CN, the pattern portion PT may be deposited up to the exposed bridge pattern BP along the second side surface SS2 of the separator SPR, and through this, the pattern portion PT and the bridge portion BR may be electrically connected to each other.

In an embodiment of the inventive concept, an additional dummy layer DML-A may be disposed on the upper surface US-B of the first bridge line BL1. The additional dummy layer DML-A may include a first additional dummy layer DML-A1 and a second additional dummy layer DML-A2 disposed on the first additional dummy layer DML-A1.

An end of the dummy layer DML located on the second side surface SS2 of the separator SPR and an end of the first additional dummy layer DML-A1 located on the upper surface US-B of the first bridge line BL1 may be separated and spaced apart from each other. That is, the first additional dummy layer DML-A1 may be formed simultaneously with the dummy layer DML in the process of depositing the intermediate layer IML and may be formed by being separated from the dummy layer DML along the edge of the separator SPR without a separate patterning process.

An end of the second sensing pattern SP2 located on the second side surface SS2 of the separator SPR and an end of the second additional dummy layer DML-A2 located on the upper surface US-B of the first bridge line BL1 may be separated and spaced apart from each other. That is, the second additional dummy layer DML-A2 may be formed simultaneously with the second sensing pattern SP2 in the process of depositing the second electrode EL2 and may be formed by being separated from the second sensing pattern SP2 along the edge of the separator SPR without a separate patterning process.

Meanwhile, as the first additional dummy layer DML-A1 and the dummy layer DML may be connected to each other, the first additional dummy layer DML-A1 may be disposed between the second sensing pattern SP2 and the first bridge line BL1. In this case, although the second sensing pattern SP2 and the first bridge line BL1 do not come in direct contact with each other, if a portion of the dummy layer DML and the first additional dummy layer DML-A1 formed along the second side surface SS2 of the separator SPR is thin so that the second sensing pattern SP2 and the first bridge line BL1 can be electrically connected to each other, the second sensing pattern SP2 may be considered to be in contact with the first bridge line BL1.

FIGS. 11, 12A, and 12B are enlarged views illustrating the first connection part CNP1 of the first bridge line BL1 and the connection form of the first connection part CNP1 of the first bridge line BL1, but the description given above with reference to FIGS. 11, 12A, and 12B may be equally applied to the second connection part CNP2 of the first bridge line BL1 and the first and second connection parts CNP1 and CNP2 of the second bridge line BL2 of FIG. 10A.

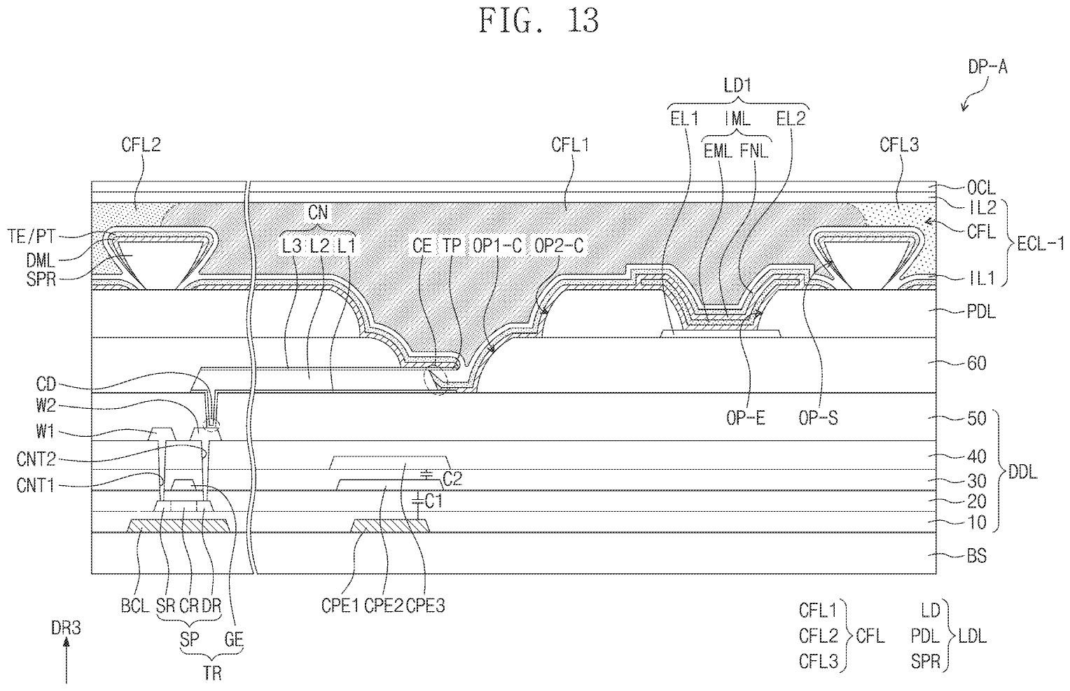

FIG. 13 is a cross-sectional view of a display panel according to an embodiment of the inventive concept. Same/similar reference numerals will be used for the same/similar elements as those described in FIGS. 1 to 12B, and redundant descriptions will be omitted.

Referring to FIG. 13, a display panel DP-A according to an embodiment of the inventive concept may include a base layer BS, a driving device layer DDL, a sixth insulating layer 60, a connection line CN, a light-emitting device layer LDL, a sensing electrode TE, an encapsulation layer ECL-1, and an overcoating layer OCL.

In this embodiment, the encapsulation layer ECL-1 may include a first inorganic layer IL1, color filter layers CFL disposed on the first inorganic layer IL1, and a second inorganic layer IL2 disposed on the color filter layers CFL. Compared to the encapsulation layer ECL in the display panel DP described above in FIG. 5, the color filter layers CFL may be disposed in the encapsulation layer ECL-1 according to this embodiment instead of the organic layer OL (see FIG. 5).

The description of the first inorganic layer IL1 and the second inorganic layer IL2 described above with reference to FIG. 5 may be similarly applied to the first inorganic layer IL1 and the second inorganic layer IL2 according to this embodiment. That is, the first inorganic layer IL1 and the second inorganic layer IL2 may protect the light-emitting device LD1 from moisture and oxygen from outside the display panel DP-A.

The color filter layers CFL may include color filters. The color filters may have a predetermined arrangement. For example, the color filters may be arranged in consideration of the light-emitting colors of the light-emitting devices LD1 included in the display panel DP-A. According to an embodiment of the inventive concept, the color filter layers CFL may include a first color filter layer CFL1, a second color filter layer CFL2, and a third color filter layer CFL3 according to the color filters included.

The first color filter layer CFL1, the second color filter layer CFL2, and the third color filter layer CFL3 may transmit light of different colors. For example, the first color filter layer CFL1 may transmit red light, the second color filter layer CFL2 may transmit blue light, and the third color filter layer CFL3 may transmit green light. However, the colors of the light transmitted by the first color filter layer CFL1, the second color filter layer CFL2, and the third color filter layer CFL3 are not limited thereto and may be selected in consideration of the light-emitting colors of the light-emitting devices LD1, LD2, and LD3 (see FIG. 4B).

As described above with reference to FIG. 4B, the light-emitting devices LD1, LD2, and LD3 (see FIG. 4B) may include a first light-emitting device LD1, a second light-emitting device LD2 (see FIG. 4B) and a third light-emitting device LD3 (see FIG. 4B) that emit light of different colors. For example, the first light-emitting device LD1 may emit red light, the second light-emitting device LD2 (see FIG. 4B) may emit blue light, and the third light-emitting device LD3 (see FIG. 4B) may emit green light.

In this embodiment, the color filter layers CFL1, CFL2, and CFL3 may be disposed to overlap the light-emitting devices LD1, LD2, and LD3 (see FIG. 4B), and in this case, each of the color filter layers CFL1 CFL2, and CFL3 may overlap a corresponding light-emitting device LD1, LD2, or LD3 (see FIG. 4B) so that the colors of light transmitted by the color filter layers CFL1, CFL2, and CFL3 may correspond to the colors of light emitted from the light-emitting devices LD1, LD2, and LD3 and provided to the color filter layers CFL1 CFL2, and CFL3.

For example, the first color filter layer CFL1, the second color filter layer CFL2, and the third color filter layer CFL3 may be disposed to overlap the first light-emitting device LD1, the second light-emitting device LD2 (see FIG. 4B), and the third light-emitting device LD3 (see FIG. 4B), respectively. FIG. 13 representatively illustrates one first light-emitting device LD1 among the light-emitting devices LD1, LD2, and LD3 (see FIG. 4B) and exemplarily illustrates that the first color filter layer CFL1 is disposed to overlap the first light-emitting device LD1. Meanwhile, in a manner similar to that of the first color filter layer CFL1, the second color filter layer CFL2 and the third color filter layer CFL3 may also be disposed to overlap the second light-emitting device LD2 (see FIG. 4B) and the third light-emitting device LD3 (see FIG. 4B), respectively.

Edge of the first color filter layer CFL1, the second color filter layer CFL2, and the third color filter layer CFL3 may be disposed on the separator SPR. That is, regions of the light-emitting devices LD1, LD2, and LD3 (see FIG. 4B) are defined by the separator SPR, and corresponding to the separated light-emitting devices LD1, LD2, and LD3 (see FIG. 4B), each of the first color filter layer CFL1, the second color filter layer CFL2, and the third color filter layer CFL3 may be disposed to cover a region enclosed by the separator SPR.

The overcoating layer OCL may be disposed on an encapsulation layer ECL-1. Specifically, the overcoating layer OCL may be disposed on the second inorganic layer IL2. Compared to the display panel DP described above in FIG. 5, in the display panel DP-A according to this embodiment, the light control layer RSL (see FIG. 5) may be omitted and the overcoating layer OCL may be disposed on the encapsulation layer ECL-1.

The overcoating layer OCL may contain an organic material, and a flat surface may be provided on the upper surface of the overcoating layer OCL. Meanwhile, in an embodiment of the inventive concept, the over coating layer OCL may be omitted.

As the encapsulation layer ECL-1 includes the color filter layers CFL, the encapsulation layer ECL-1 may play the role of a color filter as well as the role of encapsulating the first light-emitting device LD1 and the sensing electrode TE and therefore, the display panel DP-A according to this embodiment may not include a separate light control layer RSL (see FIGS. 5 and 7) on the encapsulation layer ECL-1. Accordingly, the overall thickness of the display panel DP-A may be further reduced, and the manufacturing process thereof may be further simplified as well.

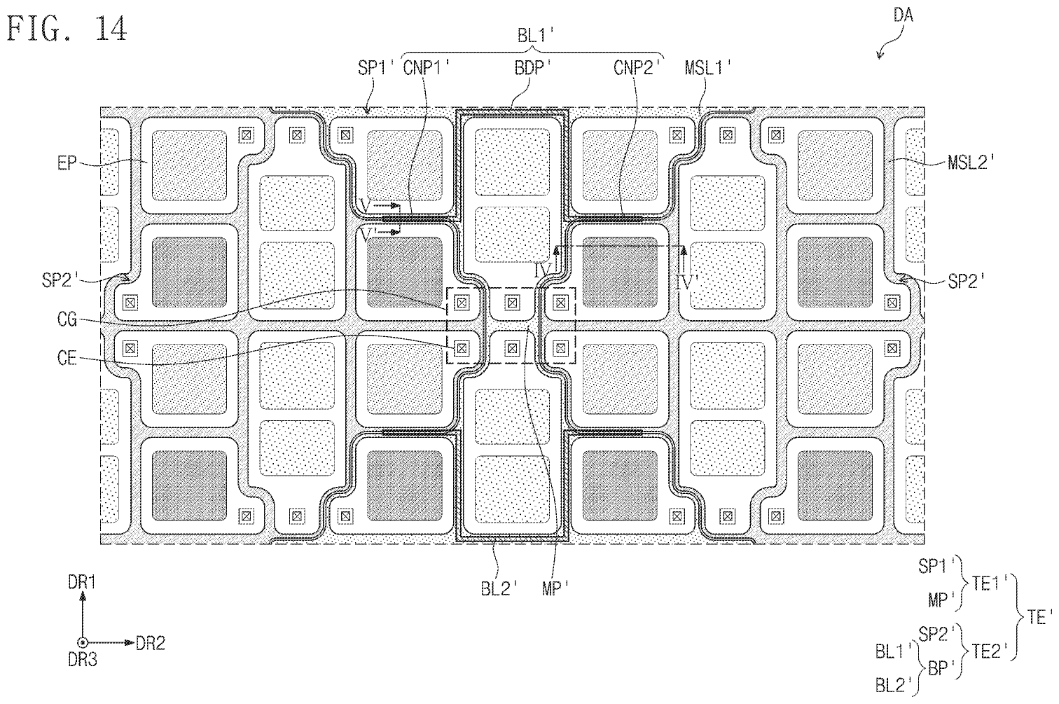

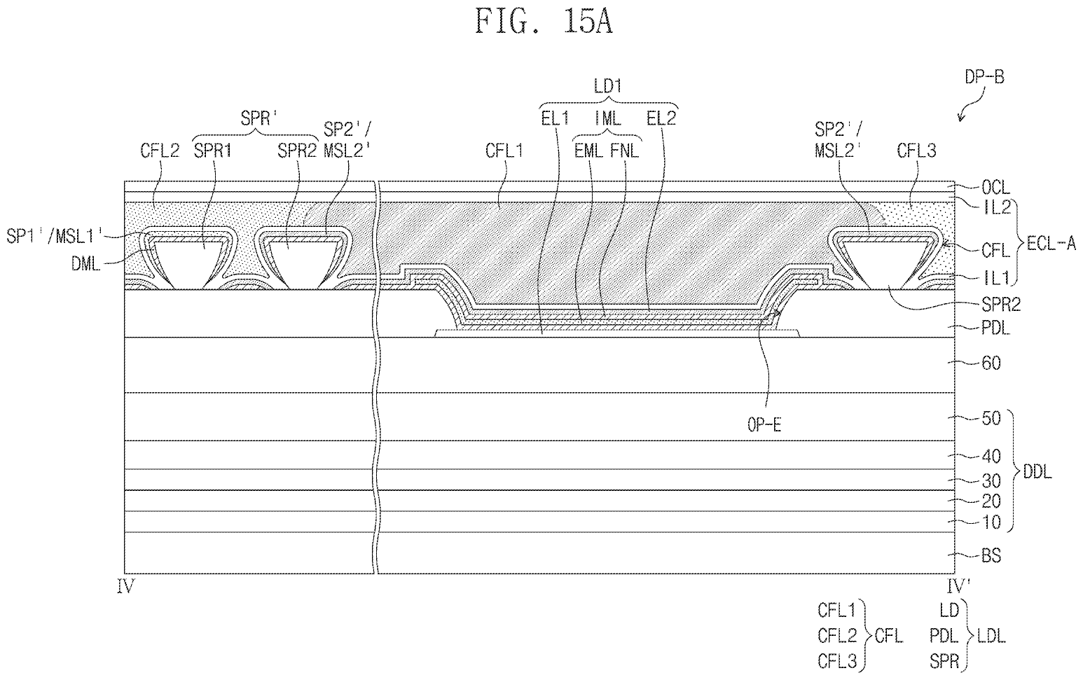

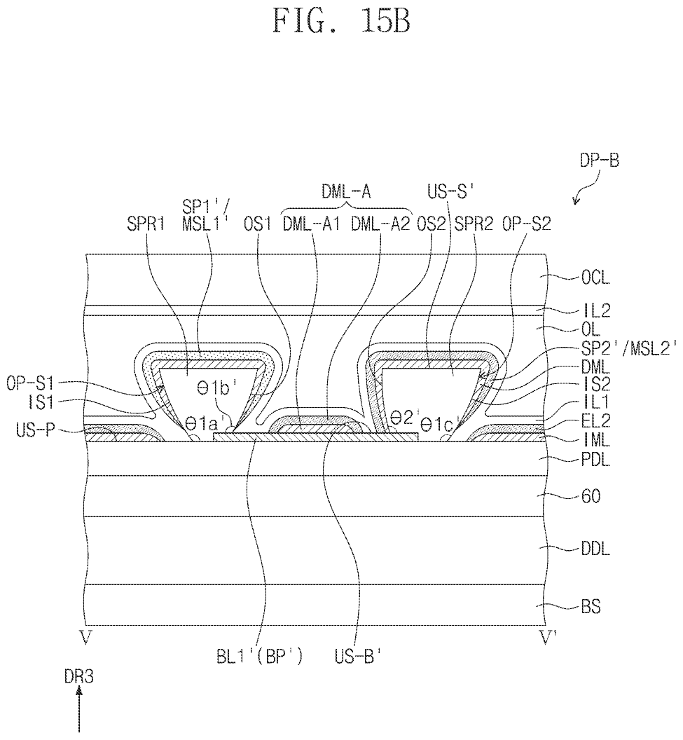

FIG. 14 is an enlarged plan view of a partial region of the display panel according to an embodiment of the inventive concept. FIG. 15A is a cross-sectional view of the display panel illustrating a portion corresponding to line IV-IV′ of FIG. 14. FIG. 15B is a cross-sectional view of the display panel illustrating a portion corresponding to line V-V′ of FIG. 14. Same/similar reference numerals will be used for the same/similar elements as those described in FIGS. 1 to 13, and redundant descriptions will be omitted.

Referring to FIGS. 14 and 15A, a sensing electrode TE′ may include a first sensing electrode TE1′ including first sensing patterns SP1′ and an intermediate pattern MP′, and a second sensing electrode TE2′ including second sensing patterns SP2′ and a bridge pattern BP′. The first sensing patterns SP1′ and the intermediate pattern MP′ in one first sensing electrode TE1′ may form an integral shape, and the integrally formed first sensing patterns SP1′ and intermediate pattern MP′ may include a first mesh line MSL1′. Each of the second sensing patterns SP2′ of the second sensing electrode TE2′ may include a second mesh line MSL2′.

In this embodiment, the first mesh line MSL1′ and the second mesh line MSL2′ adjacent to each other may be spaced apart from each other between adjacent emitting parts EP. That is, both the first mesh line MSL1′ and the second mesh line MSL2′ may be disposed between the adjacent emitting parts EP. Accordingly, all of the outer edge portion of the first mesh line MSL1′ may directly face the outer edge portion of the second mesh line MSL2′ in a direction crossing the extension direction. In this case, in an embodiment of the inventive concept, the first mesh line MSL1′ and the second mesh line MSL2′ may be disconnected between the adjacent emitting parts EP, and therefore, portions facing each other in the extension direction may not be included.

According to this embodiment, the first mesh line MSL1′ and the second mesh line MSL2′ may form a boundary within a relatively short distance, and thus, the sensing region of the first sensing electrode TE1′ and the sensing region of the second sensing electrode TE2′ may expand so as to be adjacent to each other, and sensing sensitivity may be improved at a boundary between the first sensing electrode TE1′ and the second sensing electrode TE2′ adjacent to each other. In other words, as the sensing region of the sensing electrodes TE′ widens, a display panel DP-B with improved sensing sensitivity may be provided.

Meanwhile, FIG. 14 illustrates that the first mesh line MSL1′ forming the inner side of a first sensing pattern SP1′ and the first mesh line MSL1′ forming the outer edge of the first sensing pattern SP1′ have different widths and the second mesh line MSL2′ forming the inner side of the second sensing pattern SP2′ and the second mesh line MSL2′ forming the outer edge of the second sensing pattern SP2′ have different widths, but the embodiment of the inventive concept is not limited thereto, and the first mesh line MSL1′ and the second mesh line MSL2′ may have a uniform width as a whole.

In this embodiment, the first mesh line MSL1′ and the second mesh line MSL2′ may be respectively disposed on separators SPR′ different from each other. That is, the separators SPR′ may include a first separator SPR1 overlapping the first mesh line MSL1′ and a second separator SPR2 overlapping the second mesh line MSL2′. As the first separator SPR1 and the second separator SPR2 are provided so as to be separated from each other, the first mesh line MSL1′ and the second mesh line MSL2′ may be provided so as to be separated from each other although a separate process is not performed in order to make the first mesh line MSL1′ and the second mesh line MSL2′ disconnected and spaced apart from each other on one separator SPR′.

Referring to FIGS. 14 and 15B, adjacent second sensing patterns SP2′ may be electrically connected to each other through the bridge pattern BP′. The bridge pattern BP′ may be disposed to be spaced apart from the contact group CG. In other words, the bridge pattern BP′ may not cross the emission connection parts CE in the contact group CG.

The bridge pattern BP′ may include a first bridge line BL1′ and a second bridge line BL2′. The first bridge line BL1′ and the second bridge line BL2′ may be spaced apart from each other in the first direction DR1. Each of the first bridge line BL1′ and the second bridge line BL2′ may include a first connection part CNP1′, a second connection part CNP2′, and a bent portion BDP′. The description of the shape of the first connection part CNP1, the second connection part CNP2, and the bent portion BDP given above with reference to FIG. 10A may be similarly applied to the first connection part CNP1′, the second connection part CNP2′, and the bending portion BDP′ according to this embodiment.

In this embodiment, a portion of the first connection part CNP1′ may overlap and be covered by the first separator SPR1 and overlap the first sensing pattern SP1′ formed of the first mesh line MSL1′. Another portion of the first connection part CNP1′ may overlap and be covered by the second separator SPR2, and overlap the second sensing pattern SP2′ formed of the second mesh line MSL2′. As the remaining portion of the first connection part CNP1′ may not overlap and be covered by the first and second separators SPR1 and SPR2, the remaining portion thereof may be exposed from the separators SPR′.

The first separator SPR1 may include a first inner side surface IS1 defining a separating opening OP-S1 and a first outer side surface OS1 opposite to the first inner side surface IS1 and forming the outer edge of the first separator SPR1 in a cross sectional view. An interior angle θ1a′ (hereinafter referred to as a first inner side taper angle θ1a′) between the first inner side surface IS1 and the upper surface US-P of the pixel defining layer PDL may be an obtuse angle. An interior angle θ1b′ (hereinafter referred to as a first outer side taper angle θ1b′) between the first outer side surface OS1 and the upper surface US-P of the pixel defining layer PDL may also be an obtuse angle. In an embodiment of the inventive concept, each of the first inner side taper angle θ1a′ and the first outer side taper angle θ1b′ may be greater than about 95 degrees.

In the first separator SPR1, as the first inner side taper angle θ1a′ has a taper angle sufficient to disconnect the deposition layer, the first sensing pattern SP1′ formed of the first mesh line MSL1′ on the first inner side surface IS1 may be separated or electrically disconnected from the second electrode EL2. In addition, in the first separator SPR1, as the first outer side taper angle θ1b′ also has a taper angle sufficient to dis connect the deposition layer, the first sensing pattern SP1′ formed of the first mesh line MSL1′ on the first outer side surface OS1 may be separated or electrically disconnected from the second additional dummy layer DML-A2. That is, the first sensing pattern SP1′ may not be in contact with and electrically connected to the first bridge line BL1′.

The second separator SPR2 may include a second inner side surface IS2 defining a separating opening OP-S2 and a second outer side surface OS2 opposite to the second inner side surface IS2 and forming the outer edge of the second separator SPR2 in a cross sectional view. An interior angle θ1c′ (hereinafter referred to as a second inner side taper angle θ1c′) formed between the second inner side surface IS2 and the upper surface US-P of the pixel defining layer PDL may be an obtuse angle. An interior angle θ2′ (hereinafter referred to as a second outer side taper angle θ2′) between the second outer side surface OS2 and the upper surface US-P of the pixel defining layer PDL may be an obtuse angle or a right angle. In this case, the second outer side taper angle θ2′ may be smaller than the second inner side taper angle θ1c′. In addition, the second outer side taper angle θ2′ may be smaller than each of the first inner side taper angle θ1a′ and the first outer side taper angle θ1b′. In an embodiment of the inventive concept, each of the first inner side taper angle θ1a′, the first outer side taper angle θ1b′, and the second inner side taper angle θ1c′ may be greater than about 95 degrees, and the second outer side taper angle θ2′ may be from about 90 degrees to about 95 degrees.

In the second separator SPR2, as the second inner side taper angle θ1c′ is a taper angle sufficient to separate the deposition layer, the second sensing pattern SP2′ formed of the second mesh line MSL2′ on the second inner side surface IS2 may be separated or electrically disconnected from the second electrode EL2. On the other hand, in the second separator SPR2, as the second outer side taper angle θ2′ is a relatively small taper angle, the deposition layer may be deposited while covering the entire second outer side surface OS2 and come in contact with the exposed first bridge line BL1′. That is, in this embodiment, the second sensing pattern SP2′ formed of the second mesh line MSL2′ may extend along the second outer side surface OS2 from the upper surface US-S′ of the second separator SPR2 and come in contact with the upper surface US-B′ of the first bridge line BL1′ of the bridge pattern BP′. Accordingly, the second sensing pattern SP2′ may be connected to the first bridge line BL1′ of the bridge pattern BP′.

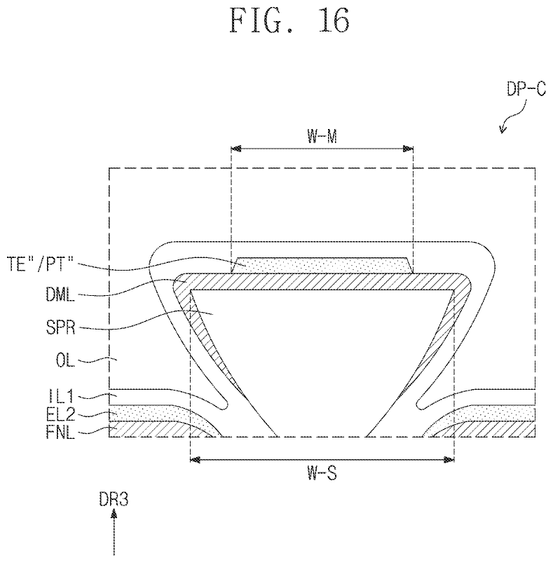

FIG. 16 is an enlarged cross-sectional view illustrating a partial region of a display panel according to an embodiment of the inventive concept. FIG. 16 illustrates an enlarged cross-section of a region in which one separator SPR is disposed.

Referring to FIG. 16, in this embodiment, the pattern portion PT″ of the sensing electrode TE″ disposed on the separator SPR may not overlap the second electrode EL2 in a plan view. In this case, the width W-M of the mesh lines MSL1 and MSL2 (see FIG. 9) included in the pattern portion PT″ in a cross sectional view may be smaller than or equal to the width W-S of the separator SPR in a cross sectional view. In this specification, the width W-S of the separator SPR may mean the maximum width of the separator SPR. The widths of the mesh lines MSL1 and MSL2 (see FIG. 9) may be selected within a range not to overlap the second electrode EL2 in a plan view.

According to an embodiment of the inventive concept, by minimizing a region in which the pattern portion PT″ of the sensing electrode TE″ and the second electrode EL2, to which a variable voltage is applied, overlap each other in a plan view, the formation of parasitic capacitance between the sensing electrode TE″ and the second electrode EL2 may be minimized, thus reducing noise generation. Accordingly, the display panel DP-C with improved sensing sensitivity may be provided.

According to this inventive concept, it is possible to provide sensing electrodes with improved sensing sensitivity as well as pixels with reduced afterimage defects and improved lifetime.

According to this inventive concept, the display panel includes a connection line connecting the electrode of the light-emitting device to the transistor, and the connection line includes a driver connection part connected to the transistor and an emission connection part connected to the electrode of the light-emitting device and spaced apart from the driver connection part in a plan view. According to this inventive concept, by disposing the bridge pattern, which is insulated from and crosses the first sensing electrodes and electrically connects adjacent second sensing electrodes to each other, to be spaced apart from the emission connection part, the effect of a change in electric field in the emission connection part may be minimized. Accordingly, as the sensing electrodes with reduced noise are included in the display panel, the display panel having improved sensing sensitivity may be provided.

According to this inventive concept, in the process of depositing the second electrode, as the deposition layer formed on the separator is electrically disconnected from the second electrode and used as a sensing electrode, a sensing function may be performed without forming a separate sensing layer on the panel. Accordingly, a process may be simplified and the display panel having a reduced thickness may be provided.

Although the above has been described with reference to preferred embodiments of the present inventive concept, those skilled in the art or those having ordinary knowledge in the art do not deviate from the spirit and technical scope of the present inventive concept described in the claims to be described later. It will be understood that the present inventive concept can be variously modified and changed within the scope not specified. Therefore, the technical scope of the present inventive concept is not limited to the contents described in the detailed description of the specification, but should be determined by the claims.

What is claimed is:

1. A display panel comprising:
a light-emitting device comprising a first electrode, a second electrode, and an intermediate layer disposed between the first electrode and the second electrode and comprising a light-emitting layer;
a pixel defining layer having a light-emitting opening defined therein, the pixel defining layer not covering at least a center portion of the first electrode;
a separator disposed on the pixel defining layer and having a separating opening which is defined therein and overlaps the light-emitting opening; and
a sensing electrode comprising a pattern portion overlapping the separator and a bridge portion electrically connected to the pattern portion,
wherein:
at least a portion of the pattern portion is disposed on the separator and the pattern portion is electrically disconnected from the second electrode along an edge of the separator; and
the bridge portion is disposed on the pixel defining layer, and
wherein:
the bridge portion includes a first portion which overlaps the separator and a second portion which does not overlap the separator.

2. The display panel of claim 1, wherein the separator comprises:
a first side surface defining the separating opening; and
a second side surface opposite to the first side surface, and
wherein an interior angle formed between the second side surface and an upper surface of the pixel defining layer is smaller than an interior angle formed between the first side surface and the upper surface of the pixel defining layer.

3. The display panel of claim 2, wherein:
the separator includes a connection opening, the separator not covering at least a portion of the bridge portion;
a portion of an inner side surface of the separator defining the connection opening corresponds to the second side surface; and
the pattern portion is connected to the bridge portion in the connection opening.

4. The display panel of claim 1, wherein the pattern portion comprises a mesh line having a mesh opening defined therein, and
wherein the mesh opening is disposed in a region corresponding to the separating opening to overlap the separating opening.

5. The display panel of claim 4, further comprising:
a transistor electrically connected to the second electrode; and
a connection line electrically connecting the transistor to the second electrode,
wherein:
the second electrode is disposed on the first electrode in a region overlapping the light-emitting opening; and
the connection line comprises:
a first connection part connected to the second electrode and spaced apart from the light-emitting opening in a plan view; and
a second connection part connected to the transistor.

6. The display panel of claim 5, wherein each of the separating opening and the mesh opening overlaps both the light-emitting opening and the first connection part in a plan view.

7. The display panel of claim 4, wherein:
the light-emitting device includes a plurality of light-emitting devices;
the light-emitting opening includes a plurality of light-emitting openings which are disposed to correspond to the plurality of light-emitting devices, respectively;
the separating opening includes a plurality of separating opening which are disposed to correspond to the light-emitting openings, respectively; and
the mesh opening includes a plurality of mesh openings each of which is disposed to correspond to one or more of the separating openings.

8. The display panel of claim 7, wherein the pattern portion comprises:
first sensing patterns arranged in a first direction;
an intermediate pattern disposed between the first sensing patterns and having an integral shape with the first sensing patterns; and
second sensing patterns arranged in a second direction crossing the first direction, and
wherein:
a first mesh line includes a mesh line of the first sensing patterns and the intermediate pattern; and
a second mesh line includes a mesh line of the second sensing patterns.

9. The display panel of claim 8, wherein the first mesh line and the second mesh line are disposed on the same layer and spaced apart from each other.

10. The display panel of claim 8, wherein the bridge portion electrically connects the second sensing patterns adjacent to each other.

11. The display panel of claim 8, wherein the bridge portion comprises at least one bridge line, and
wherein each of the at least one bridge line comprises:
a first connection part connected to one of the second sensing patterns;
a second connection part connected to another one of the second sensing patterns disposed adjacent to the one of the second sensing patterns and spaced apart from the first connection part in the second direction; and
a bent portion disposed between the first connection part and the second connection part.

12. The display panel of claim 11, wherein:
the bent portion overlaps the first sensing patterns and is completely overlapped with the separator.

13. The display panel of claim 11, wherein the first connection part and the second connection part are spaced apart from each other with at least one of the light-emitting openings interposed therebetween.

14. The display panel of claim 11, wherein:
the separator includes a first connection opening in which the separator on a portion of the first connection part is removed, and a second connection opening in which the separator on a portion of the second connection part is removed;
the one of the second sensing patterns is connected to the first connection part though the first connection opening; and
the another one of the second sensing patterns disposed adjacent to the one of the second sensing patterns is connected to the second connection part through the second connection opening.

15. The display panel of claim 14, wherein the pattern portion extends along an inner side surface of the separator defining the first connection opening and is connected to the bridge portion.

16. The display panel of claim 14, wherein an interior angle between an inner side surface of the separator defining the first connection opening and an upper surface of the pixel defining layer is from about 90 degrees to about 95 degrees.

17. The display panel of claim 8, wherein the separator comprises a first separator and a second separator spaced apart from each other, and
wherein the first mesh line overlaps the first separator and the second mesh line overlaps the second separator.

18. The display panel of claim 17, wherein:
a portion of the bridge portion overlaps the first separator;
another portion of the bridge portion overlaps the second separator; and
a remaining portion of the bridge portion is not covered by the first separator and the second separator, and
wherein the pattern portion is connected to the remaining portion of the bridge portion.

19. The display panel of claim 17, wherein:
the first separator comprises a first outer side surface facing the second separator and overlapping the bridge portion; and
the second separator comprises a second outer side surface facing the first outer side surface and overlapping the bridge portion, and
wherein an interior angle formed between the second outer side surface and an upper surface of the pixel defining layer is smaller than an interior angle formed between the first outer side surface and the upper surface of the pixel defining layer.

20. The display panel of claim19, wherein the second sensing pattern extends along the second outer side surface and is connected to the bridge portion.

21. The display panel of claim 1, further comprising:
transistors electrically connected to second electrodes of the light-emitting devices, respectively; and
connection lines electrically connecting the transistors to the second electrodes, respectively,
wherein each of the connection lines comprises:
a first connection part connected to a corresponding second electrode among the second electrodes; and
a second connection part connected to a corresponding transistor among the transistors, and
wherein the first connection parts of the connection lines are disposed adjacent to each other in a predetermined arrangement to form contact groups.

22. The display panel of claim 21, wherein the bridge portion is spaced apart from the contact groups in a plan view.

23. The display panel of claim 21, wherein:
the bridge portion comprises a first bridge line and a second bridge line spaced apart from each other in a first direction with one of the contact groups interposed therebetween;
a bent portion of the first bridge line protrudes in a direction away from the one of the contact groups from each of a first connection part and a second connection part of the first bridge line; and
a bent portion of the second bridge line protrudes in a direction away from the one of the contact groups from each of a first connection part and a second connection part of the second bridge line.

24. The display panel of claim 1, further comprising a dummy layer disposed between the separator and the pattern portion,
wherein the dummy layer is separated from the intermediate layer along the edge of the separator.

25. The display panel of claim 24, further comprising an additional dummy layer disposed on a portion of the bridge portion not covered by the separator,
wherein the additional dummy layer comprises:
a first additional dummy layer separated from the dummy layer along the edge of the separator; and
a second additional dummy layer disposed on the first additional dummy layer and electrically separated from the pattern portion along the edge of the separator.

26. The display panel of claim 1, further comprising:
an encapsulation layer covering the light-emitting device and the sensing electrode and comprising a first inorganic layer, an organic layer, and a second inorganic layer sequentially stacked in a thickness direction; and
a light control layer disposed on the encapsulation layer.

27. The display panel of claim 1, further comprising:
a first inorganic layer covering the light-emitting device and the sensing electrode;
a color filter layer disposed on the first inorganic layer; and
a second inorganic layer disposed on the color filter layer.

28. The display panel of claim 27, wherein:
the light-emitting device comprises a first light-emitting device, a second light-emitting device, and a third light-emitting device that emit different colors; and
the color filter layer comprises:
a first color filter layer overlapping the first light-emitting device;
a second color filter layer overlapping the second light-emitting device; and
a third color filter layer overlapping the third light-emitting device.

29. The display panel of claim 28, further comprising an overcoating layer disposed on the second inorganic layer.

30. A display panel, comprising:
a transistor;
a pixel defining layer having a light-emitting opening defined therein;
a light-emitting device comprising a first electrode at least a center of which is not covered by the pixel defining layer, a second electrode electrically connected to the transistor and disposed on the first electrode in a region overlapping the light-emitting opening, and a light-emitting layer disposed between the first electrode and the second electrode;
a separator disposed on the pixel defining layer and having a separating opening defined therein, the separating opening overlapping the light-emitting opening and the second electrode being disposed in the separating opening; and
a sensing electrode comprising a pattern portion overlapping the separator and disposed on the separator, and a bridge portion disposed between the pixel defining layer and the separator,
wherein:
the bridge portion is disposed to be spaced apart from the separating opening and partially covered by the separator; and
the pattern portion is connected to a portion of the bridge portion not covered by the separator.

31. The display panel of claim 30, wherein the separator comprises:
a first side surface defining the separating opening; and
a second side surface opposite to the first side surface, and
wherein an interior angle formed between the second side surface and an upper surface of the pixel defining layer is smaller than an interior angle formed between the first side surface and the upper surface of the pixel defining layer.

32. The display panel of claim 31, wherein:
the separator includes a connection opening in which the separator on a portion of the bridge portion is removed;
a portion of an inner side surface of the separator defining the connection opening corresponds to the second side surface; and
the pattern portion is connected to the bridge portion through the connection opening.

33. The display panel of claim 31, wherein:
the separator comprises a first separator and a second separator spaced apart from each other,
wherein:
a portion of the bridge portion overlaps the first separator;
another portion of the bridge portion overlaps the second separator;
a remaining portion of the bridge portion is not covered by the first separator and the second separator; and
the second side surface corresponds to an outer side surface of the second separator facing the first separator, and
wherein the interior angle formed between the second side surface and the upper surface of the pixel defining layer is smaller than an interior angle formed between an outer side surface of the first separator facing the second side surface and the upper surface of the pixel defining layer.

34. The display panel of claim 30, wherein the pattern portion is electrically separated from the second electrode along an edge of the separator.

35. The display panel of claim 30, further comprising a connection line electrically connecting the transistor to the second electrode,
wherein the connection line comprises:
a first connection part connected to the second electrode and spaced apart from the light-emitting opening in a plan view; and
a second connection part connected to the transistor.
